(19) United States
(12) Patent Application Publication
(10) Pub. No.: US 2020/0328168 A1
(43) Pub. Date: Oct. 15, 2020

(54) SEMICONDUCTOR CHIPS INCLUDING REDISTRIBUTION LAYER

(71) Applicant: Samsung Electronics Co., Ltd., Suwon-si (KR)

(72) Inventor: Junghyun Roh, Suwon-si (KR)

(73) Assignee: Samsung Electronics Co., Ltd., Suwon-si (KR)

(21) Appl. No.: 16/567,426

(22) Filed: Sep. 11, 2019

(30) Foreign Application Priority Data
Apr. 12, 2019 (KR) 10-2019-0043296

(51) Int. Cl. H01L 23/00

(52) U.S. Cl. CPC H01L 24/02; H01L 24/05; H01L 2224/0218; H01L 2224/02317; H01L 2924/3511; H01L 2224/02373; H01L 2224/05008; H01L 2224/05025; H01L 2224/0236

(57) ABSTRACT

A semiconductor chip includes a redistribution layer having an improved reliability. The semiconductor chip includes a device layer on a semiconductor substrate, a wiring structure on the device layer, a cover insulating layer on the wiring structure, and a redistribution layer. The device layer includes a semiconductor device. The wiring structure includes an internal connection pad electrically connected to the semiconductor device. The cover insulating layer includes a first recess filled with a connection via connected to the internal connection pad and a second recess having a depth that is less than that of the first recess. The redistribution layer in connected to the connection via and extends along an upper surface of the cover insulating layer.

### CROSS-REFERENCE TO RELATED APPLICATION

This application claims the benefit of Korean Patent Application No. 10-2019-0043296, filed on Apr. 12, 2019, in the Korean Intellectual Property Office, the disclosure of which is incorporated herein in its entirety by reference.

### BACKGROUND

The inventive concepts relate to semiconductor chips, and more particularly to semiconductor chips including a redistribution layer.

As electronic products are required to be miniaturized, multi-functionalized, and have high-performance, methods of mounting and connecting semiconductor chips to electronic products are diverse. Accordingly, a redistribution layer is formed on a semiconductor chip and an external connection pad is freely disposed, thereby satisfying the requirement for mounting and connecting various electronic products.

### SUMMARY

The inventive concepts provide semiconductor chips including a redistribution layer having an improved reliability.

The inventive concepts provide semiconductor chips to achieve the technical solution.

According to some example embodiments, a semiconductor chip may include a device layer on a semiconductor substrate, a wiring structure on the device layer, a cover insulating layer on the wiring structure, and a redistribution layer. The device layer may include a semiconductor device. The wiring structure may include an internal connection pad electrically connected to the semiconductor device. The cover insulating layer may include a first recess and a second recess. The first recess may be filled with a connection via. The connection via may be connected to the internal connection pad. A magnitude of a depth of the second recess may be less than a magnitude of a depth of the first recess. The redistribution layer may be connected to the connection via and may extend along an upper surface of the cover insulating layer.

According to some example embodiments, a semiconductor chip may include a device layer on a semiconductor substrate, a wiring layer on the device layer, a wiring via on the device layer and connected to the wiring layer, and a wiring insulating layer at least partially between the wiring layer and the wiring via, the wiring layer including an internal connection pad, a cover insulating layer, a connection via, a redistribution layer, and a stress balance pattern on the cover insulating layer. The cover insulating layer may include a first recess extending through an interior of the cover insulating layer, from an upper surface of the cover insulating layer to a lower surface of the cover insulating layer, to expose the internal connection pad of the wiring layer. The cover insulating layer may include a second recess extending into the interior of the cover insulating layer from the upper surface of the cover insulating layer towards the lower surface of the cover insulating layer. The connection via may fill the first recess. The connection via may be connected to the internal connection pad. The redistribution layer may be connected to the connection via. The redistribution layer may extend along the upper surface of the cover insulating layer. The stress balance pattern may fill the second recess. The stress balance pattern may be isolated from direct contact with the redistribution layer.

According to some example embodiments, a semiconductor chip may include a device layer on a semiconductor substrate, a plurality of wiring layers on the device layer, a plurality of wiring vias connected to the plurality of wiring layers, and a wiring insulating layer filling between the plurality of wiring layers and the plurality of wiring vias, the plurality of wiring layers including a plurality of internal connection pads, a cover insulating layer including a plurality of connection via holes extending through an interior of the cover insulating layer from an upper surface of the cover insulating layer to a lower surface of the cover insulating layer to expose the plurality of internal connection pads, a plurality of connection vias filling separate, respective connection via holes of the plurality of connection via holes, a plurality of redistribution layers connected to separate, respective connection vias of the plurality of connection vias, the plurality of redistribution layers extending along the upper surface of the cover insulating layer, and a stress balance pattern on the cover insulating layer, the stress balance pattern isolated from direct contact with the plurality of redistribution layers.

### BRIEF DESCRIPTION OF THE DRAWINGS

Example embodiments of the inventive concepts will be more clearly understood from the following detailed description taken in conjunction with the accompanying drawings in which:

FIG. 1 is a plan view showing a semiconductor chip according to some example embodiments of the inventive concepts;

FIG. 2 is a plan view showing a semiconductor chip according to some example embodiments of the inventive concepts;

FIG. 3 is a plan view showing a semiconductor chip according to some example embodiments of the inventive concepts;

FIG. 4 is a plan view showing a semiconductor chip according to some example embodiments of the inventive concepts;

FIGS. 5A, 5B, 5C, 5D, and 5E are cross-sectional views sequentially illustrating a method of manufacturing a semiconductor chip, according to some example embodiments of the inventive concepts;

FIG. 6 is a cross-sectional view illustrating semiconductor chips according to embodiments of the inventive concepts;

FIG. 7 is a plan view showing a semiconductor chip according to some example embodiments of the inventive concepts;

FIG. 8 is a plan view showing a semiconductor chip according to some example embodiments of the inventive concepts;

FIG. 9 is a plan view showing a semiconductor chip according to some example embodiments of the inventive concepts;

FIG. 10 is a plan view showing a semiconductor chip according to some example embodiments of the inventive concepts;

FIG. 11 is a cross-sectional view illustrating a method of manufacturing a semiconductor chip, according to some example embodiments of the inventive concepts;

FIG. 12 is a cross-sectional view illustrating semiconductor chips according to embodiments of the inventive concepts;

FIG. 13 is a plan view showing a semiconductor chip according to some example embodiments of the inventive concepts;

FIG. 14 is a plan view showing a semiconductor chip according to some example embodiments of the inventive concepts;

FIG. 15 is a plan view showing a semiconductor chip according to some example embodiments of the inventive concepts;

FIG. 16 is a plan view showing a semiconductor chip according to some example embodiments of the inventive concepts;

FIGS. 17A, 17B, 17C, and 17D are cross-sectional views sequentially illustrating a method of manufacturing a semiconductor chip, according to some example embodiments of the inventive concepts; and

FIG. 18 is a cross-sectional view illustrating semiconductor chips according to embodiments of the inventive concepts.

### DETAILED DESCRIPTION

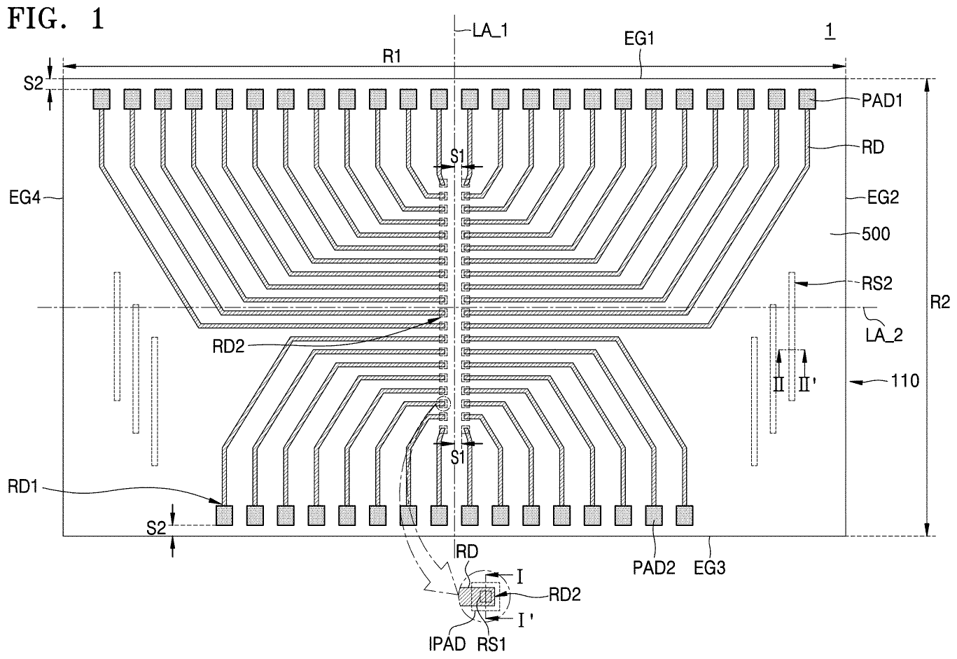

FIG. 1 is a plan view showing a semiconductor chip 1 according to some example embodiments of the inventive concepts.

Referring to FIG. 1, the semiconductor chip 1 includes a semiconductor substrate 110 and a plurality of redistribution layers RD disposed on the semiconductor substrate 110. The semiconductor substrate 110 may have first to fourth edges EG1, EG2, EG3, and EG4 that are sequentially connected. The first edge EG1 and the third edge EG3 may extend in a major axis direction of the semiconductor chip 1, and the second edge EG2 and the fourth edge EG4 may extend in a minor axis direction of the semiconductor chip 1.

It will be understood that an element that is “on” another element may be above or below the other element. It will be further understood that an element that is “on” another element may be “directly” on the other element, such that the elements are in direct contact with each other, or may be “indirectly” on the other element, such that the elements are isolated from direct contact with each other by one or more interposing spaces and/or structures.

The plurality of redistribution layers RD may extend to electrically connect a plurality of internal connection pads IPAD to a plurality of external connection pads PAD1 and PAD2 of the semiconductor chip 1. That is, the plurality of internal connection pads IPAD may be connected to one end of the plurality of redistribution layers RD, and the plurality of external connection pads PAD1 and PAD2 may be connected to the other end thereof. It is illustrated in FIG. 1 that a length of each of the plurality of redistribution layers RD decreases as the distance between the internal connection pads IPAD and the external connection pads PAD1 and PAD2, which are connected to each other, decreases and the length of each of the plurality of redistribution layers RD has the same width and extends, but this is for convenience of illustration and is not limited thereto. For example, when the distance between the internal connection pads IPAD and the external connection pads PAD1 and PAD2, which are connected to each other, is close, the redistribution layer RD may have a bypass path to increase an extension length, or when the distance between the internal connection pads IPAD and the external connection pads PAD1 and PAD2, which are connected to each other, is far, at least a part of the redistribution layers RD may have a greater width.

In some example embodiments, including the example embodiments shown in FIG. 1, the plurality of internal connection pads IPAD may be center pads arranged in a planar manner along the center (e.g., in parallel with central axis LA_1) of the semiconductor substrate 110. For example, as shown in FIG. 1, the internal connection pads IPAD may extend in one of separate linear, symmetrical patterns aligned with (e.g., extending in parallel with) a central axis LA_1 of the semiconductor substrate 110, where the central axis LA_1 is positioned equidistantly from opposite edges EG2, EG4 of the semiconductor substrate 110, where each internal connection pad IPAD that is a center pad is positioned a distance S1 from the central axis LA_1 where distance S1 is equal to or less than about 10% of the magnitude of the distance R1 of the edges EG2, EG4 from the central axis LA_1. In some example embodiments, including the example embodiments shown in FIG. 1, the plurality of external connection pads PAD1 and PAD2 may be edge pads arranged in a planar manner along the edge of the semiconductor substrate 110, but are not limited thereto. For example, as shown in FIG. 1, the external connection pads PAD1 and PAD2 may extend in one of separate linear patterns aligned with (e.g., extending in parallel with) a central axis LA_2 of the semiconductor substrate 110, where the central axis LA_2 is positioned equidistantly from opposite edges EG1, EG3 of the semiconductor substrate 110, where each external connection pad PAD1 and PAD2 that is an edge pad is positioned a distance S2 from one of the opposite edges EG1, EG3 where distance S2 is equal to or less than about 10% of the magnitude of the distance R2 of the edges EG1, EG3 from the central axis LA_2. It will be understood that, when the terms “about” or “substantially” are used in this specification in connection with a numerical value, it is intended that the associated numerical value include a tolerance of ±10% around the stated numerical value. When ranges are specified, the range includes all values therebetween such as increments of 0.1%.

The plurality of external connection pads PAD1 and PAD2 may be arranged asymmetrically with each other at the edge of the semiconductor substrate 110, i.e., among the first to fourth edges EG1, EG2, EG3, and EG4, the first edge EG1 and the third edge EG3 that are opposite to each other and/or the second edge EG2 and the fourth edge EG4 that are opposite to each other.

For example, the plurality of external connection pads PAD1 and PAD2 may include the plurality of first external connection pads PAD1 and the plurality of second external second pads PAD2 that are disposed along the first edge EG1 and the third edge EG3 that are opposite to each other. In this case, the number and/or arrangement of the plurality of first external connection pads PAD1 and the number and/or arrangement of the plurality of second external second pads PAD2 may be different from each other. In some example embodiments, the number (e.g., quantity) of the plurality of first external connection pads PAD1 disposed along the first edge EG1 may be greater than the number of the plurality of second external connection pads PAD2 disposed along the third edge EG3. Restated, in some example embodiments, the plurality of external connection pads PAD1, PAD2 may include a first set of external connection pads (e.g., first external connection pads PAD1) and a second set of external connection pads (e.g., second external connection pads PAD2), where the first set of external connection pads are adjacent to a first edge EG1 of the semiconductor substrate 110, the second set of external connection pads are adjacent to a second edge EG2 of the semiconductor substrate 110 where the first and second edges are opposite edges of the semiconductor substrate 110. The first and second sets of external connection pads may include different quantities of external connection pads.

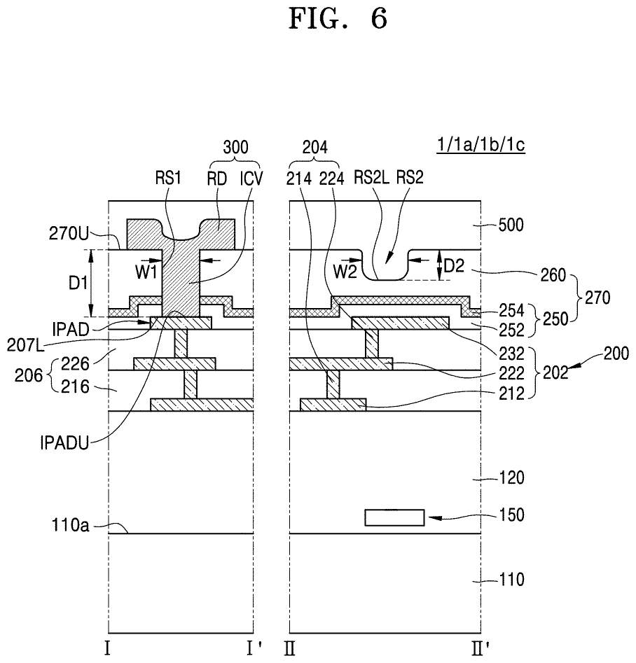

The plurality of redistribution layers RD may extend along an upper surface 270U of the cover insulating layer 270. The plurality of redistribution layers RD may be electrically connected to the plurality of internal connection pads IPAD through a plurality of connection vias (ICV in FIG. 6) filling (e.g., entirely filling) separate, respective first recesses RS1 of a plurality of first recesses RS1 (e.g., connection via holes). Restated, the plurality of redistribution layers RD may be connected to separate, respective connection vias ICV of the plurality of connection vias ICV. In some example embodiments, the plurality of connection vias ICV may fill (e.g., entirely fill) separate, respective first recesses RS1 of the plurality of first recesses RS1. As shown in at least FIG. 1, a first end RD1 of each redistribution layer RD of the plurality of redistribution layers RD may be connected to a separate external connection pad PAD1, PAD2 of the plurality of external connection pads PAD1, PAD2, and an opposite, second end RD2 of each distribution layer RD of the plurality of redistribution layers RD may be connected to a separate connection via ICV of the plurality of connection vias ICV.

At least one second recess RS2 may be disposed in a part of the semiconductor substrate 110 where the plurality of redistribution layers RD are not disposed. For example, when the plurality of redistribution layers RD are densely arranged on the semiconductor substrate 110 relatively adjacent to the first edge EG1, the at least one second recess RS2 may be disposed in a part of the semiconductor substrate 110 adjacent to the second edge EG2 and the third edge EG3 where the plurality of redistribution layers RD are not disposed or the plurality of redistribution layers RD are arranged relatively less densely and/or a part of the semiconductor substrate 110 adjacent to the third edge EG3 and the fourth edge EG4.

Although it is illustrated in FIG. 1 that the plurality of second recesses RS2 having substantially the same width and extending in a uniform length in the same direction are arranged in the semiconductor chip 1, for example, a plurality of second recesses RS2 having different widths, different extension directions, and different extension lengths may be arranged.

Each of the plurality of first recesses RS1 may extend from an upper surface to a lower surface to penetrate a cover insulating layer 270 (FIG. 6), and the at least one second recess RS2 may extend from the upper surface of the cover insulating layer 270 the inside but may not extend to the lower surface. The extension length of the first recess RS1 from the upper surface to the lower surface of the cover insulating layer 270 may be greater than the extension length of the second recess RS2. For example, a depth of the first recess RS1 from the upper surface of the cover insulating layer 270 may have a value greater than that of a depth of the second recess RS2. In some example embodiments, the width of the second recess RS2 may have a value greater than that of the width of the first recess RS1.

A cover protecting layer 500 may be formed on the semiconductor substrate 110 and expose the external connection pads PAD1 and PAD2. The cover protecting layer 500 may cover the plurality of redistribution layers RD and may fill the at least one second recess RS2.

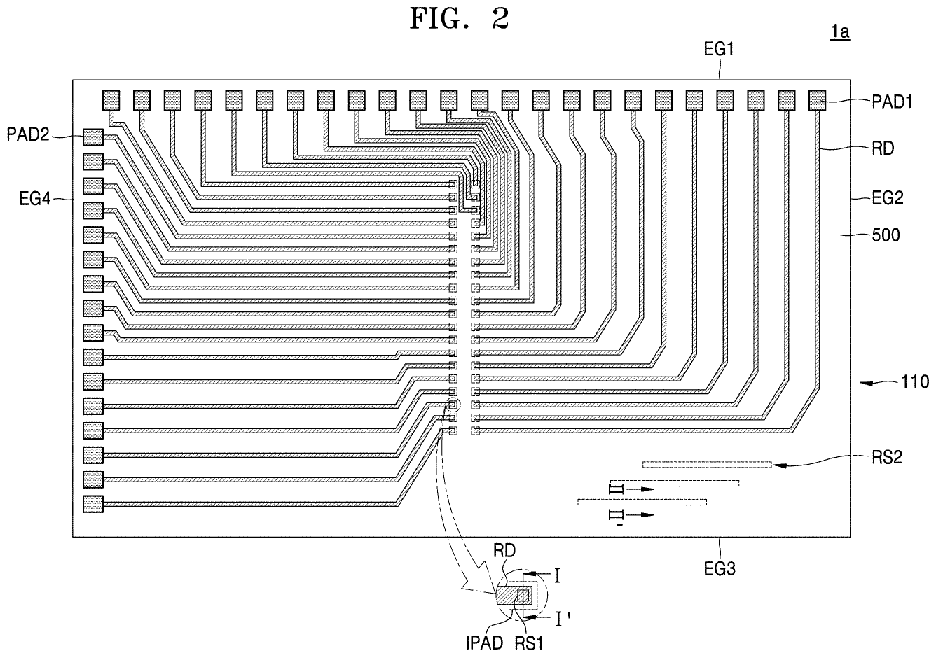

FIG. 2 is a plan view showing a semiconductor chip 1a according to some example embodiments of the inventive concepts.

Referring to FIG. 2, the semiconductor chip 1a includes the semiconductor substrate 110 and the plurality of redistribution layers RD disposed on the semiconductor substrate 110. The semiconductor substrate 110 may have the first to fourth edges EG1, EG2, EG3, and EG4 that are sequentially connected. The first edge EG1 and the third edge EG3 may extend in a major axis direction of the semiconductor chip 1a, and the second edge EG2 and the fourth edge EG4 may extend in a minor axis direction of the semiconductor chip 1a.

The plurality of redistribution layers RD may extend to electrically connect the plurality of internal connection pads IPAD to the plurality of external connection pads PAD1 and PAD2 of the semiconductor chip 1a.

In some example embodiments, the plurality of internal connection pads IPAD may be center pads arranged in a planar manner along the center of the semiconductor substrate 110, and the plurality of external connection pads PAD1 and PAD2 may be edge pads arranged in a planar manner along the edge of the semiconductor substrate 110, but are not limited thereto.

The plurality of external connection pads PAD1 and PAD2 may be arranged asymmetrically with each other at the edge of the semiconductor substrate 110, i.e., among the first to fourth edges EG1, EG2, EG3, and EG4, the first edge EG1 and the fourth edge EG4 that are connected to each other and/or the second edge EG2 and the third edge EG3 that are connected to each other.

For example, the plurality of external connection pads PAD1 and PAD2 may include the plurality of first external connection pads PAD1 and the plurality of second external second pads PAD2 that are respectively disposed along the first edge EG1 and the fourth edge EG4 that are connected to each other. In this case, the number and/or arrangement of the plurality of first external connection pads PAD1 and the number and/or arrangement of the plurality of second external second pads PAD2 may be different from each other. In some example embodiments, the number (e.g., quantity) of the plurality of first external connection pads PAD1 disposed along the first edge EG1 may be greater than the number of the plurality of second external connection pads PAD2 disposed along the fourth edge EG4. Restated, in some example embodiments, the plurality of external connection pads PAD1, PAD2 may include a first set of external connection pads (e.g., first external connection pads PAD1) and a second set of external connection pads (e.g., second external connection pads PAD2), where the first set of external connection pads are adjacent to a first edge EG1 of the semiconductor substrate 110, the second set of external connection pads are adjacent to a second edge (e.g., fourth edge EG4) of the semiconductor substrate 110 where the first and second edges are connected to each other (e.g., first edge EG1 and fourth edge EG4 are connected to each other). The first and second sets of external connection pads may include different quantities of external connection pads.

The redistribution layers RD may be electrically connected to the internal connection pad IPAD through the connection via (ICV in FIG. 6) filling the first recess RS1.

The at least one second recess RS2 may be disposed in a part of the semiconductor substrate 110 on which the redistribution layer RD is not disposed. For example, when the redistribution layer RD is arranged densely arranged on the semiconductor substrate 110 relatively adjacent to the first edge EG1 and the fourth edge EG4, the at least one second recess RS2 may be disposed in a part of the semiconductor substrate 110 adjacent to the second edge EG2 and the third edge EG3 where the redistribution layer RD is not disposed or the redistribution layer RD is arranged relatively less densely.

The first recess RS1 may extend from an upper surface to a lower surface to penetrate the cover insulating layer 270 (FIG. 6), and the at least one second recess RS2 may extend from the upper surface of the cover insulating layer 270 to the inside but may not extend to the lower surface. An extension length of the first recess RS1 may have a value greater than that of an extension length of the second recess RS2. For example, a depth of the first recess RS1 from an upper surface of the cover insulating layer 270 may have a value greater than that of a depth of the second recess RS2. In some example embodiments, a width of the second recess RS2 may have a value greater than that of a width of the first recess RS1.

The cover protecting layer 500 may be formed on the semiconductor substrate 110 and expose the external connection pads PAD1 and PAD2. The cover protecting layer 500 may cover the plurality of redistribution layers RD and may fill the at least one second recess RS2.

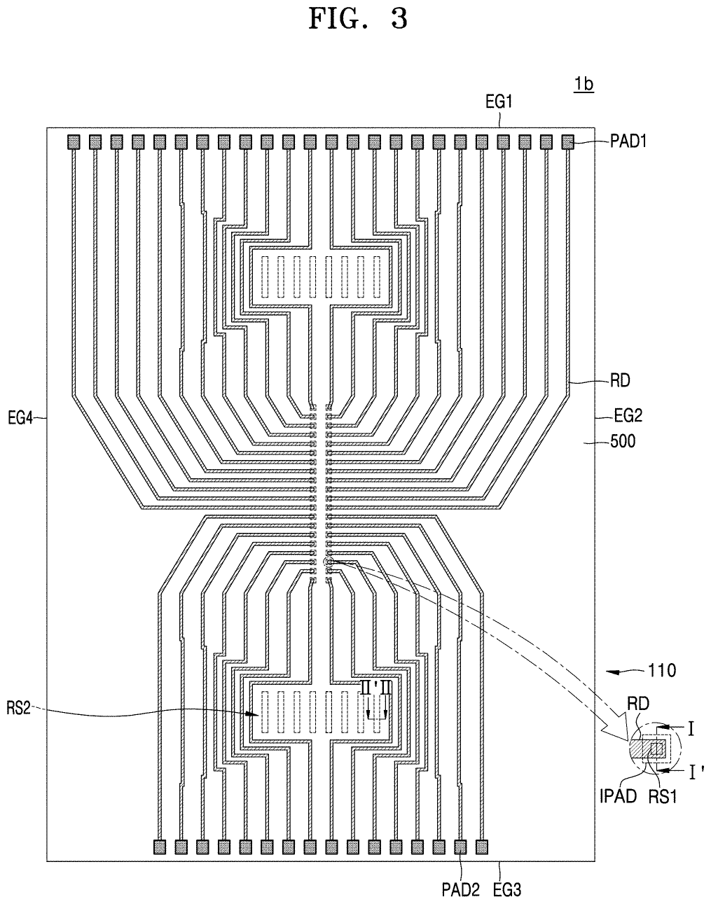

FIG. 3 is a plan view showing a semiconductor chip 1b according to some example embodiments of the inventive concepts.

Referring to FIG. 3, the semiconductor chip 1b includes the semiconductor substrate 110 and the plurality of redistribution layers RD disposed on the semiconductor substrate 110. The semiconductor substrate 110 may have the first to fourth edges EG1, EG2, EG3, and EG4 that are sequentially connected. The first edge EG1 and the third edge EG3 may extend in a minor axis direction of the semiconductor chip 1b, and the second edge EG2 and the fourth edge EG4 may extend in a major axis direction of the semiconductor chip 1b.

The plurality of redistribution layers RD may extend to electrically connect the plurality of internal connection pads IPAD to the plurality of external connection pads PAD1 and PAD2 of the semiconductor chip 1b.

In some example embodiments, the plurality of internal connection pads IPAD may be center pads arranged in a planar manner along the center of the semiconductor substrate 110, and the plurality of external connection pads PAD1 and PAD2 may be edge pads arranged in a planar manner along the edge of the semiconductor substrate 110, but are not limited thereto.

The plurality of external connection pads PAD1 and PAD2 may be arranged asymmetrically with each other at the edge of the semiconductor substrate 110, i.e., among the first to fourth edges EG1, EG2, EG3, and EG4, the first edge EG1 and the third edge EG3 that are opposite to each other and/or the second edge EG2 and the fourth edge EG4 that are opposite to each other.

For example, the plurality of external connection pads PAD1 and PAD2 may include the plurality of first external connection pads PAD1 and the plurality of second external second pads PAD2 that are respectively disposed along the first edge EG1 and the fourth edge EG4 that are connected to each other. In this case, the number and/or arrangement of the plurality of first external connection pads PAD1 and the number and/or arrangement of the plurality of second external second pads PAD2 may be different from each other. In some example embodiments, the number of the plurality of first external connection pads PAD1 disposed along the first edge EG1 may be greater than the number of the plurality of second external connection pads PAD2 disposed along the third edge EG3.

The redistribution layers RD may be electrically connected to the internal connection pad IPAD through the connection via (ICV in FIG. 6) filling the first recess RS1.

The at least one second recess RS2 may be disposed in a part of the semiconductor substrate 110 on which the redistribution layer RD is not disposed. Some of the plurality of redistribution layers RD may extend with a shape that bypasses the at least one second recess RS2. For example, the at least one second recess RS2 may be disposed on any part selected on the semiconductor substrate 110, and some of the plurality of redistribution layers RD may be spaced apart from (e.g., isolated from direct contact with) the at least one second recess RS2.

In some example embodiments, the at least one second recess RS2 may be disposed between the internal connection pad IPAD and the plurality of first external connection pads PAD1 and between the internal connection pad IPAD and the plurality of second external connection pads PAD2. For example, each of some of the plurality of redistribution layers RD connected to the plurality of first external connection pads PAD1 and some of the plurality of redistribution layers RD connected to the plurality of second external connection pads PAD2 may extend with a shape that bypasses the at least one second recess RS2.

The first recess RS1 may extend from an upper surface to a lower surface to penetrate the cover insulating layer 270 (FIG. 6), and the at least one second recess RS2 may extend from the upper surface of the cover insulating layer 270 to the inside but may not extend to the lower surface. An extension length of the first recess RS1 may have a value greater than that of an extension length of the second recess RS2. For example, a depth of the first recess RS1 from an upper surface of the cover insulating layer 270 may have a value greater than that of a depth of the second recess RS2. In some example embodiments, a width of the second recess RS2 may have a value greater than that of a width of the first recess RS1.

The cover protecting layer 500 may be formed on the semiconductor substrate 110 and expose the external connection pads PAD1 and PAD2. The cover protecting layer 500 may cover the plurality of redistribution layers RD and may fill the at least one second recess RS2.

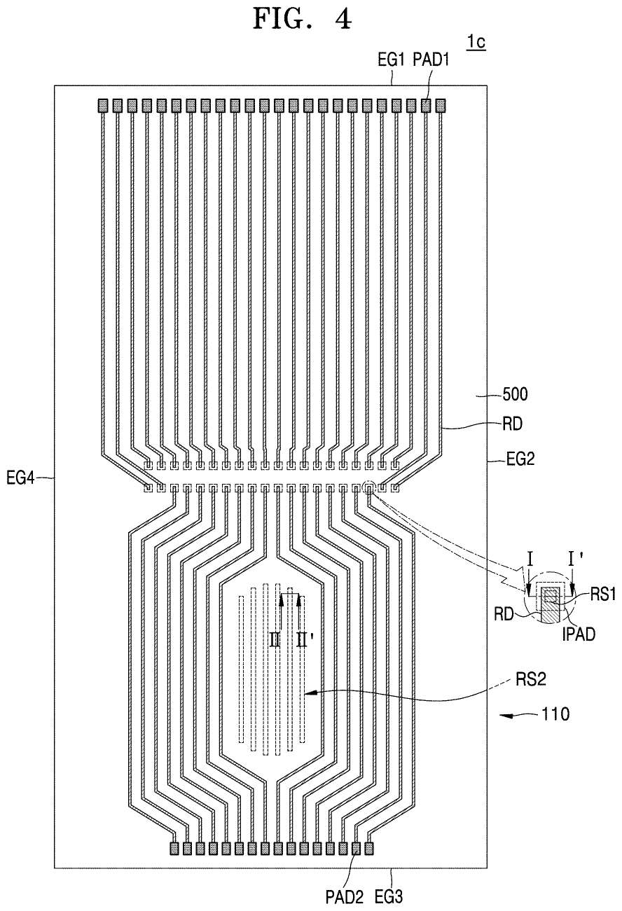

FIG. 4 is a plan view showing a semiconductor chip 1c according to some example embodiments of the inventive concepts.

Referring to FIG. 4, the semiconductor chip 1c includes the semiconductor substrate 110 and the plurality of redistribution layers RD disposed on the semiconductor substrate 110. The semiconductor substrate 110 may have the first to fourth edges EG1, EG2, EG3, and EG4 that are sequentially connected. The first edge EG1 and the third edge EG3 may extend in a minor axis direction of the semiconductor chip 1c, and the second edge EG2 and the fourth edge EG4 may extend in a major axis direction of the semiconductor chip 1c.

The plurality of redistribution layers RD may extend to electrically connect the plurality of internal connection pads IPAD to the plurality of external connection pads PAD1 and PAD2 of the semiconductor chip 1c.

In some example embodiments, the plurality of internal connection pads IPAD may be center pads arranged in a planar manner along the center of the semiconductor substrate 110, and the plurality of external connection pads PAD1 and PAD2 may be edge pads arranged in a planar manner along the edge of the semiconductor substrate 110, but are not limited thereto.

The plurality of external connection pads PAD1 and PAD2 may be arranged asymmetrically with each other at the edge of the semiconductor substrate 110, i.e., among the first to fourth edges EG1, EG2, EG3, and EG4, the first edge EG1 and the third edge EG3 that are opposite to each other and/or the second edge EG2 and the fourth edge EG4 that are opposite to each other.

For example, the plurality of external connection pads PAD1 and PAD2 may include the plurality of first external connection pads PAD1 and the plurality of second external second pads PAD2 that are respectively disposed along the first edge EG1 and the fourth edge EG4 that are connected to each other. In this case, the number and/or arrangement of the plurality of first external connection pads PAD1 and the number and/or arrangement of the plurality of second external second pads PAD2 may be different from each other. In some example embodiments, the number of the plurality of first external connection pads PAD1 disposed along the first edge EG1 may be greater than the number of the plurality of second external connection pads PAD2 disposed along the third edge EG3.

The redistribution layers RD may be electrically connected to the internal connection pad IPAD through the connection via (ICV in FIG. 6) filling the first recess RS1.

The at least one second recess RS2 may be disposed in a part of the semiconductor substrate 110 on which the redistribution layer RD is not disposed. For example, some of the plurality of redistribution layers RD may extend with a shape that bypasses the at least one second recess RS2.

In some example embodiments, the at least one second recess RS2 may not be disposed between the internal connection pad IPAD and the plurality of first external connection pads PAD1 and the at least one second recess RS2 may be disposed between the internal connection pad IPAD and the plurality of second external connection pads PAD2. For example, some of the plurality of redistribution layers RD connected to the plurality of second external connection pads PAD2 may extend with a shape that bypasses the at least one second recess RS2.

The first recess RS1 may extend from an upper surface to a lower surface to penetrate the cover insulating layer 270 (FIG. 6), and the at least one second recess RS2 may extend from the upper surface of the cover insulating layer 270 to the inside but may not extend to the lower surface. An extension length of the first recess RS1 may have a value greater than that of an extension length of the second recess RS2. For example, a depth of the first recess RS1 from an upper surface of the cover insulating layer 270 may have a value greater than that of a depth of the second recess RS2. In some example embodiments, a width of the second recess RS2 may have a value greater than that of a width of the first recess RS1.

The cover protecting layer 500 may be formed on the semiconductor substrate 110 and expose the external connection pads PAD1 and PAD2. The cover protecting layer 500 may cover the plurality of redistribution layers RD and may fill the at least one second recess RS2.

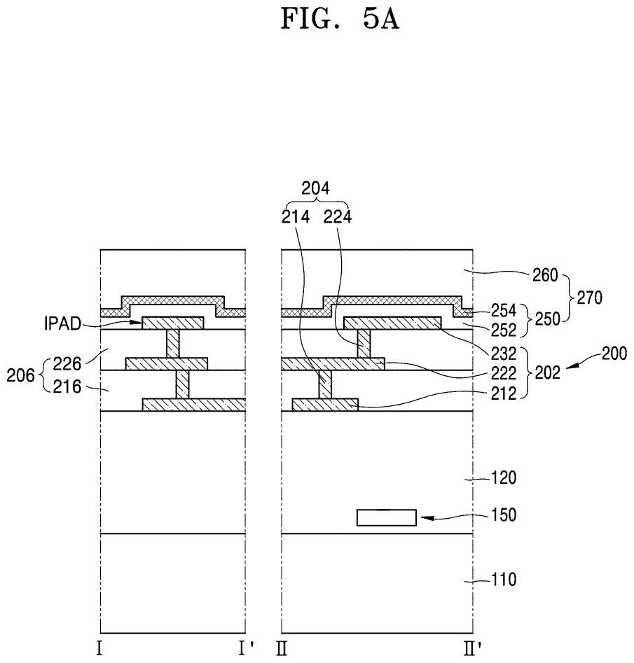

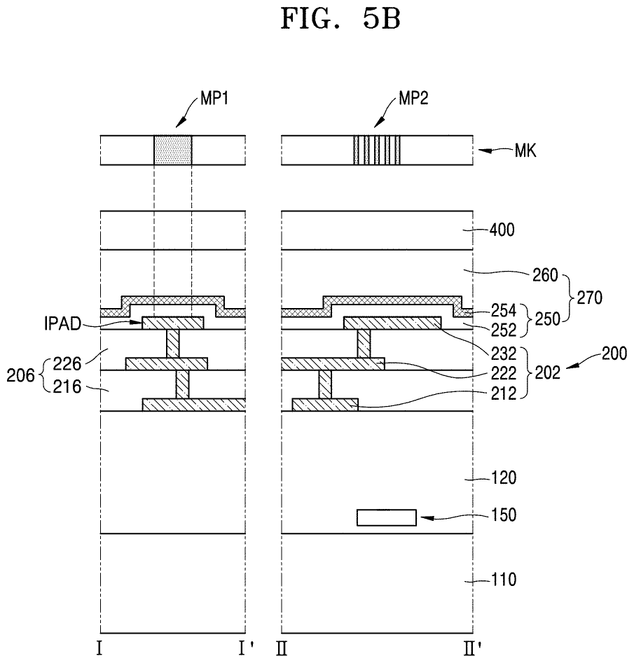

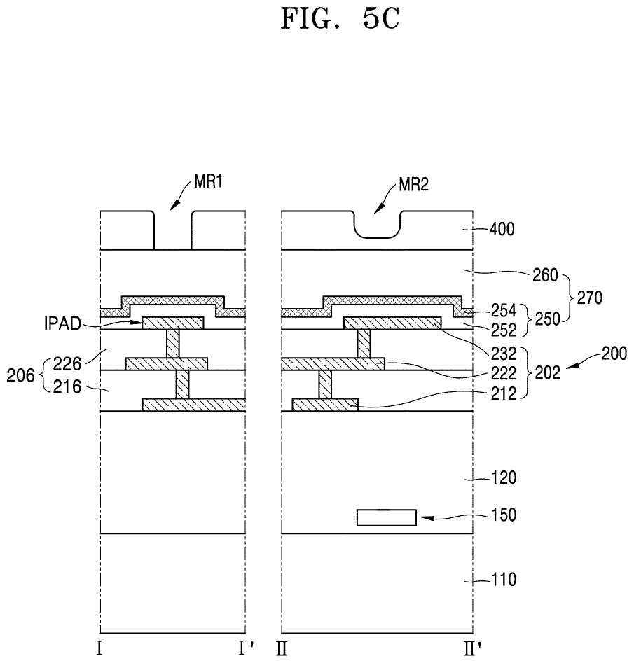

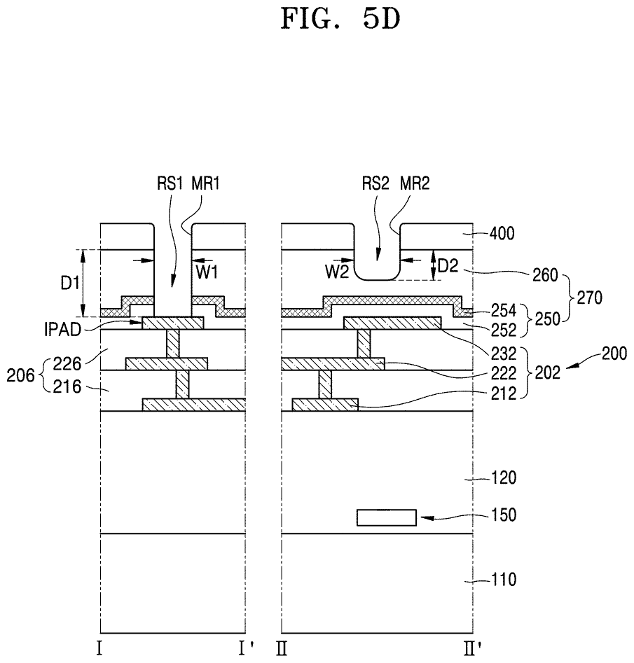

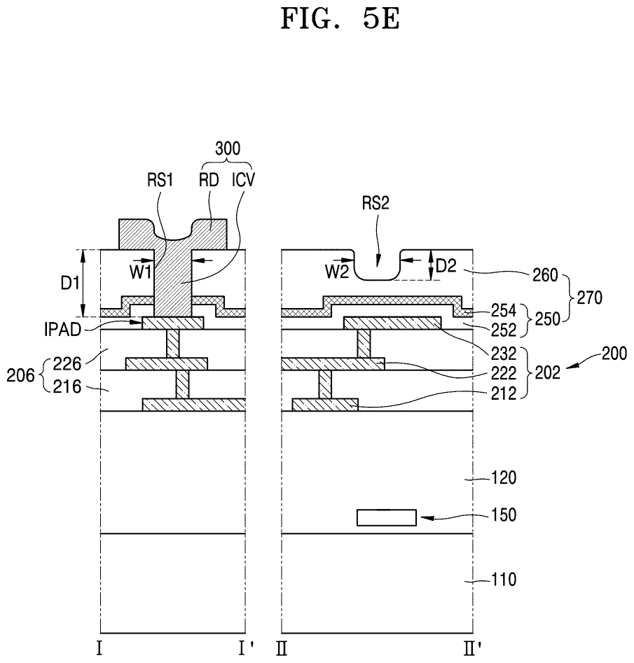

FIGS. 5A, 5B, 5C, 5D, and 5E are cross-sectional views sequentially illustrating a method of manufacturing a semiconductor chip, according to some example embodiments of the inventive concepts. Specifically, FIGS. 5A, 5B, 5C, 5D, and 5E are the cross-sectional views sequentially illustrating a method of manufacturing any one of the semiconductor chips 1, 1a, 1b and 1c shown in FIGS. 1 to 4, and illustrate cross-sections corresponding to lines I-I′ and II-II′ of FIGS. 1 to 4, respectively.

Referring to FIG. 5A, a device layer 120 including a semiconductor device 150 is formed on the semiconductor substrate 110.

The semiconductor substrate 110 may include, for example, silicon (Si). In some example embodiments, the semiconductor substrate 110 may include a semiconductor element such as germanium (Ge) or a compound semiconductor such as silicon carbide (SiC), gallium arsenide (GaAs), indium arsenide (InAs), and indium phosphide (InP). In some example embodiments, the semiconductor substrate 110 may have a silicon on insulator (SOI) structure. For example, the semiconductor substrate 110 may include a buried oxide (BOX) layer. The semiconductor substrate 110 may include a conductive region, for example, a well doped with an impurity, or a structure doped with an impurity. In addition, the semiconductor substrate 100 may have various device isolation structures such as a shallow trench isolation (STI) structure. The semiconductor substrate 110 may have an active surface and an inactive surface opposite the active surface.

The device layer 120 including the semiconductor device 150 may be formed in a portion of the semiconductor substrate 110 near the active region and on the active surface of the semiconductor substrate 110. The semiconductor device 150 may be, for example, a dynamic random access memory (DRAM) device, a static random access memory (SRAM) device, a flash memory device, an electrically erasable and programmable read-only memory (EEPROM) device, a phase-change random access memory (PRAM) device, a magnetic random access memory (MRAM) device, a resistive random access memory (RRAM) device, or various types of a plurality of individual devices for configuring a central processing unit (CPU), a graphics processing unit (GPU), or an application processor (AP).

The device layer 120 may include the semiconductor device 150, a conductive line, and a conductive plug connecting the semiconductor device 150, and an insulating layer filling between the semiconductor device 150, the conductive line, and the conductive plug, and include various types and shapes of conductive materials, semiconductor materials, and insulating materials.

A wiring structure 200, including a plurality of wiring layers 202, a plurality of wiring vias 204 connected to the plurality of wiring layers 202, and at least one wiring insulating layer 206 filling between the plurality of wiring layers 202 and the plurality of wiring vias 204, is formed on the device layer 120. The plurality of wiring layers 202 and the plurality of wiring vias 204 may be electrically connected to the semiconductor device 150.

The plurality of wiring layers 202 and the plurality of wiring vias 204 may include a wiring barrier layer and a wiring metal layer. In some example embodiments, the wiring barrier layer may include at least one material selected from Ti, TiN, Ta, and TaN. In some example embodiments, the wiring metal layer may include at least one metal selected from W, Al, and Cu. The plurality of wiring layers 202 and the plurality of wiring vias 204 may include the same material. In some example embodiments, at least some of the plurality of wiring layers 202 and the plurality of wiring vias 204 may include different materials.

The at least one wiring insulating layer 206 may include silicon oxide or an insulating material having a dielectric constant lower than that of silicon oxide.

It is illustrated in FIG. 5A that the plurality of wiring layers 202 include three layers, i.e., a first wiring layer 212, a second wiring layer 222, and a third wiring layer 232 disposed at three different layers but are not limited thereto and may include two or more or four or more layers. However, in the specification, it is described that the plurality of wiring layers 202 include three layers and the third wiring layer 232 is at the highest level (e.g., distal from an upper surface 110a of the semiconductor substrate 110) among the plurality of wiring layers 202.

A part of the third wiring layer 232 exposed by the first recess (RS1 of FIG. 6) may be used as the internal connection pad IPAD. The internal connection pad IPAD may be electrically connected to the semiconductor device 150.

The plurality of wiring vias 204 may include a first wiring via 214 electrically connecting the first wiring layer 212 to the second wiring layer 222 and a second wiring via 224 electrically connecting the second wiring layer 222 to the third wiring layer 232.

The at least one wiring insulating layer 206 may include a first wiring insulating layer 216 surrounding the first wiring via 214 and filling between the first wiring layer 212 and the second wiring layer 222 and a second wiring insulating layer 226 surrounding the second wiring via 224 and filling between the second wiring layer 222 and the third wiring layer 232.

A passivation layer 250 covering the third wiring layer 232 and the second wiring insulating layer 226 is formed. The passivation layer 250 may include silicon oxide and/or silicon nitride. In some example embodiments, the passivation layer 250 may include a first passivation layer 252 and a second passivation layer 254. For example, the first passivation layer 252 may be silicon oxide formed by a high density plasma (HDP) process and the second passivation layer 254 may be silicon nitride formed by a plasma enhanced CVD (PECVD) process.

An upper insulating layer 260 may be formed on the passivation layer 250, such that the cover insulating layer 270 includes the passivation layer 250 and the upper insulating layer 260 on the passivation layer 250. The upper insulating layer 260 may alleviate a surface step difference of an upper surface of the passivation layer 250. For example, the upper insulating layer 260 may include tetra-ethyl-ortho-silicate (TEOS). The passivation layer 250 and the upper insulating layer 260 may be collectively referred to as the cover insulating layer 270.

Referring to FIG. 5B, after a mask layer 400 covering the cover insulating layer 270 is formed, a photomask MK including a first mask pattern MP1 and a second mask pattern MP2 may be used to perform an exposure process on the mask layer 400.

The photomask MK may be a negative mask, but is not limited thereto and may be a positive mask. When the photomask MK is the negative mask, the first mask pattern MP1 may block most of light irradiated from an exposure apparatus at a position corresponding to the internal connection pad IPAD. The second mask pattern MP2 may be a plurality of scattering bar patterns and may transmit only a part of the light irradiated from the exposure apparatus and block the rest of the light. In some example embodiments, the plurality of scattering bar patterns may extend in a straight line, with each part extending in the same direction, and may be spaced from (e.g., isolated from direct contact with) one another.

Referring to FIGS. 5B and 5C, the exposure process using the photomask MK is performed to form a first mask recess MR1 and a second mask recess MR2 respectively corresponding to the first mask pattern MP1 and the second mask pattern MP2 in the mask layer 400. The first mask recess MR1 may penetrate the mask layer 400 from an upper surface to a lower surface and expose the cover insulating layer 270, that is, the upper insulating layer 260, on the lower surface. The second mask recess MR2 may extend inwardly from the upper surface of the mask layer 400, but may not penetrate the mask layer 400. Therefore, the upper insulating layer 260 may not be exposed on the lower surface of the second mask recess MR2.

Referring to FIG. 5D, an etching process is performed by using the mask layer 400 as an etch mask to remove a part of the cover insulating layer 270. A part of the cover insulating layer 270 corresponding to the first mask recess MR1 is completely removed such that the first recess RS1 exposing the internal connection pad IPAD, which is a part of the third wiring layer 232, may be formed. The etching process through the second mask recess MR2 is performed on the cover insulating layer 270 after a part of the mask layer 400 located on the lower surface of the second mask recess MR2 is removed, and thus the cover insulating layer 270 corresponding to the second mask recess MR2 may be partially removed from the upper surface such that the second recess RS2 in which the third wiring layer 232 is not exposed may be formed. A depth of the first recess RS1, i.e. a first depth D1, from the upper surface of the cover insulating layer 270 to the upper surface of the internal connection pad IPAD may have a magnitude greater than a magnitude of a second depth D2, which is a depth of the second recess RS2. In some example embodiments, the width W2 of the second recess RS2 may have a value (e.g., magnitude) greater than that (e.g., magnitude) of the width W1 of the first recess RS1. The first recess RS1 may have shape of a quadrangle, a quadrangle with round corners, or a shape close to a circle, and the width W1 of the first recess RS1 may mean a length of one side of the quadrangle or a diameter of the circle. The width W2 of the second recess RS2 may mean a width in a direction perpendicular to a direction in which the second recess RS2 extends.

In some example embodiments, a part of the upper insulating layer 260 may be exposed on the lower surface of the second recess RS2, but is not limited thereto. For example, as long as the third wiring layer 232 is not exposed on the lower surface of the second recess RS2, the second recess RS2 may penetrate the upper insulating layer 260 such that the second passivation layer RS2 may be exposed to the lower surface or may penetrate the upper insulating layer 260 and the second passivation layer 254 such that the first passivation layer 252 may be exposed to the lower surface.

After forming the first recess RS1 and the second recess RS2, the mask layer 400 may be removed. The first recess RS1 and the second recess RS2 may be formed together by a single photolithography process using one photomask (MK of FIG. 5B), but may have different depths. Therefore, because a separate process for forming the second recess RS2 does not need to be performed, the second recess RS2 may be formed without adding a manufacturing process.

Referring to FIG. 5E, a conductive material layer 300 filling the first recess RS1 and disposed on a part of the upper surface of the cover insulating layer 270, that is, a part of the upper surface of the upper insulating layer 260, is formed. The conductive material layer 300 may include a connection via ICV filling the first recess RS1 (e.g., entirely filling the first recess RS1 as shown in FIG. 5E and FIG. 6) and the redistribution layer RD electrically connected to the connection via ICV and extending along the upper surface of the upper insulating layer 260, i.e., the upper surface of the cover insulating layer 270. In some example embodiments, the connection via ICV and redistribution layer RD may be formed together to include the same material (e.g., a single, continuous piece of material). The conductive material layer 300 may configure at least some of the plurality of external connection pads PAD1 and PAD2 shown in FIGS. 1 to 4. For example, the plurality of external connection pads PAD1 and PAD2 may be a part of the conductive material layer 300, or may include the part of the conductive material layer 300 and a metal layer covering an upper surface thereof. FIG. 6 is a cross-sectional view illustrating the semiconductor chips 1, 1a, 1b, and 1c according to embodiments of the inventive concepts.

Referring to FIG. 6, the semiconductor chips 1, 1a, 1b, and 1c may include a device layer 120 on a semiconductor substrate 110, where the device layer 120 includes a semiconductor device 150. Referring to FIG. 6, the semiconductor chips 1, 1a, 1b, and 1c may include a wiring structure 200 on the device layer 120. As shown in FIG. 6, the wiring structure 200 may include an internal connection pad IPAD that may be electrically connected to the semiconductor device 150. As shown in FIG. 6, the wiring structure 200 may include a plurality of wiring layers 202 on the device layer 120, a plurality of wiring vias 204 connected to the plurality of wiring layers 202, and at least one wiring insulating layer 206 filling between the plurality of wiring layers 202 and the plurality of wiring vias 204. The internal connection pad IPAD may be included in the plurality of wiring layers 202. Still referring to FIG. 6, the semiconductor chips 1, 1a, 1b, and 1c may include a cover insulating layer 270 on the wiring structure 200. The cover insulating layer 270 may include a first recess RS1 that is entirely filled with a connection via ICV. The connection via ICV may be connected to the internal connection pad IPAD. The cover insulating layer 270 may include a second recess RS2. The second recess RS2 may have a second depth D2 that is less in magnitude than a first depth D1 of the first recess RS1. Still referring to FIG. 6, the semiconductor chips 1, 1a, 1b, and 1c may include a redistribution layer RD that is connected to the connection via ICV. The redistribution layer RD may extend along an upper surface 270U of the cover insulating layer 270.

Referring to FIG. 6, the semiconductor chips 1, 1a, 1b, and 1c may be formed by forming the redistribution layer RD and the cover protecting layer 500 covering the cover insulating layer 270. The redistribution layer RD and the cover protecting layer 500 may collectively cover the upper surface 270U of the cover insulating layer 270. The cover protecting layer 500 may cover an entirety of upper and side surfaces of the redistribution layer RD. The cover protecting layer 500 may cover the redistribution layer RD and the cover insulating layer 270. The cover protecting layer 500 may expose the plurality of external connection pads PAD1 and PAD2 shown in FIGS. 1 to 4 without covering them. The cover protecting layer 500 may be formed by coating a polymer material such as polyimide, fluorocarbon, resin, or synthetic rubber or a precursor thereof on the redistribution layer RD and the cover insulating layer 270, and then removing a part such that the plurality of external connection pads PAD1 and PAD2 are exposed. In some example embodiments, the cover protecting layer 500 may be formed from photosensitive polyimide (PSPI).

A depth of the first recess RS1 in which the connection via ICV is filled (e.g., entirely filled), that is, the first depth D1 from an upper surface of the cover insulating layer 270 to an upper surface IPADU of the internal connection pad IPAD, may have a value (e.g., magnitude) greater than that (e.g., magnitude) of a depth of the second recess RS2 in which the cover protecting layer 500 is filled, that is, the second depth D2 from the upper surface of the cover insulating layer 270 to the lowermost portion of the cover protecting layer 500. In some example embodiments, the width W2 of the second recess RS2 may have a value greater than that of the width W1 of the first recess RS1.

Because the first recess RS1 is filled with the connection via ICV, the first recess RS1 may also be referred to as a connection via hole. As shown in FIGS. 1-4, semiconductor chips 1, 1a, 1b, and 1c may include a cover insulating layer 270 that includes a plurality of first recesses RS1 (e.g., a plurality of connection via holes), where each first recess RS1 extends from an upper surface 270U to a lower surface 270L, through an entirety of the interior of the cover insulating layer 270, to each expose a separate internal connection pad IPAD of a plurality of internal connection pads IPAD and thus collectively expose the plurality of internal connection pads IPAD.

As shown in FIG. 6, the cover protecting layer 500 may fill (e.g., entirely fill) the second recess RS2. Therefore, the cover protecting layer 500 may be in contact with a lower surface RS2L of the second recess RS2. In some example embodiments, the lowermost end of the cover protecting layer 500 in contact with the lower surface of the second recess RS2 may be in contact with a portion of the upper insulating layer 260, but is not limited thereto. For example, the lowermost end of the cover protecting layer 500 in contact with the lower surface of the second recess RS2 may be in contact with a portion of the second passivation layer 254 or a portion of the first passivation layer 252.

Referring to FIGS. 1 to 6, the semiconductor chip 1 shown in FIG. 1 may include the plurality of first external connection pads PAD1 and the plurality of second external connection pads PAD2 disposed asymmetrically with respect to the first edge EG1 and the third edge EG3 that extend along a major axis direction and are opposite to each other, the semiconductor chip 1a shown in FIG. 2 may include the plurality of first external connection pads PAD1 and the plurality of second external connection pads PAD2 respectively disposed in the first edge EG1 extending along a major axis direction and the fourth edge EG4 extending along a minor axis direction and disposed asymmetrically with respect to the major axis direction and the minor axis direction respectively, and the semiconductor chips 1b and 1c shown in FIGS. 3 and 4 may include the plurality of first external connection pads PAD1 and the plurality of second external connection pads PAD2 disposed asymmetrically with respect to the first edge EG1 and the third edge EG3 that extend along the minor axis direction and are opposite to each other.

Therefore, the plurality of redistribution layers RD connecting the internal connection pad IPAD and the plurality of external connection pads PAD1 and PAD2 may be non-uniformly arranged on the semiconductor chips 1, 1a, 1b and 1c in a planar manner.

When materials constituting a semiconductor chip are arranged non-uniformly in a planar manner, warpage may occur in the semiconductor chip due to stress caused by a difference in the thermal expansion coefficient of the materials constituting the semiconductor chip. In the semiconductor chips 1, 1a, 1b and 1c according to the inventive concepts, the second recess RS2 may be arranged in a part where the stress caused by the difference in the thermal expansion coefficient of materials constituting the semiconductor chips 1, 1a, 1b and 1c may be concentrated, and thus a stress concentration may be released, which may prevent the warpage from occurring in the semiconductor chips 1, 1a, 1b, and 1c, thereby improving the reliability.

As shown in FIGS. 1, 2 and 4, when stress is concentrated due to the plurality of redistribution layers RD that are non-uniformly arranged on the semiconductor chips 1, 1a and 1c, the second recess RS2 may be disposed in a part where the plurality of redistribution layers RD are not disposed, thereby releasing stress concentration that may occur in the semiconductor chips 1, 1a, and 1c.

In some example embodiments, as shown in FIG. 3, when the stress is concentrated due to the inside of the semiconductor chip 1b, for example, the device layer 120, the plurality of wiring layers 202, and the plurality of wiring vias 204, the second recess RS2 may be disposed in a corresponding part, and the plurality of redistribution layers RD may be bypassed to be spaced apart from (e.g., isolated from direct contact with) the second recess RS2, and thus the stress concentration that may occur in the semiconductor chip 1b may be released.

In some example embodiments, at least a part of an arrangement of the second recess RS may be applied together as shown in FIGS. 1 to 4 by comprehensively analyzing the stress concentration that may occur in the semiconductor chips 1, 1a, 1b, and 1c.

The second recess RS2 functions to release the stress concentration and may be called a stress release recess, a stress release pattern, or a stress release trench.

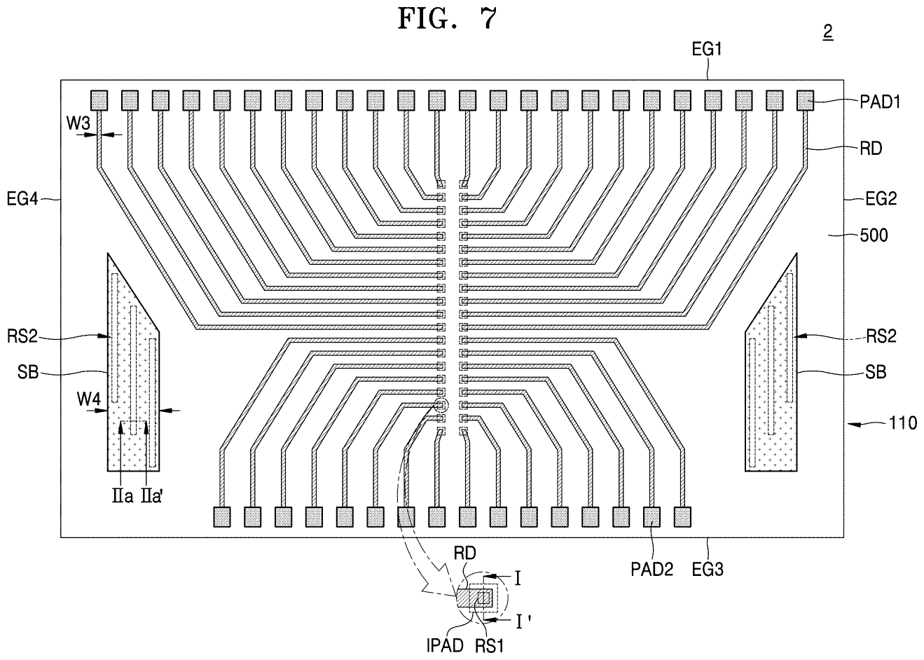

FIG. 7 is a plan view showing a semiconductor chip 2 according to some example embodiments of the inventive concepts.

Referring to FIG. 7, the semiconductor chip 2 includes the semiconductor substrate 110 and the plurality of redistribution layers RD disposed on the semiconductor substrate 110. The semiconductor chip 2 may further include at least one stress balance pattern SB unlike the semiconductor chip 1 shown in FIG. 6.

The at least one second recess RS2 may be disposed in a part of the semiconductor substrate 110 on which the redistribution layer RD is not disposed.

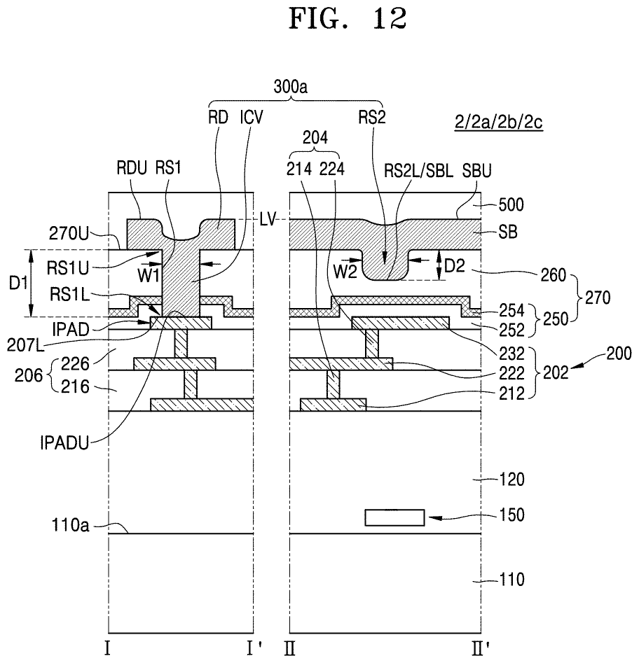

The first recess RS1 may extend from an upper surface to a lower surface to penetrate the cover insulating layer 270 (FIG. 12), and the at least one second recess RS2 may extend from the upper surface of the cover insulating layer 270 to the inside but may not extend to the lower surface. An extension length of the first recess RS1 may have a value greater than that of an extension length of the second recess RS2. For example, a depth of the first recess RS1 from an upper surface of the cover insulating layer 270 may have a value greater than that of a depth of the second recess RS2.

The at least one stress balance pattern SB filling the at least one second recess RS2 and spaced apart from (e.g., isolated from direct contact with) the plurality of redistribution layers RD may be disposed on the semiconductor substrate 110. The at least one stress balance pattern SB may include the same material as the plurality of redistribution layers RD.

A planar shape of the stress balance pattern SB shown in FIG. 7 is an example and is not limited thereto. The planar shape of the stress balance pattern SB may have, for example, various shapes of polygons. In some example embodiments, the planar shape of the stress balance pattern SB may have a bar shape extending along one direction.

In some example embodiments, a width W4 of the stress balance pattern SB may have a value (e.g., magnitude) greater than that (e.g., a magnitude) of a width W3 of the redistribution layer RD. The width W3 of the redistribution layer RD may mean a width in a direction perpendicular to a direction in which the redistribution layer RD extends. The width W4 of the stress balance pattern SB may mean a width in a direction perpendicular to a direction in which the second recess RS2 extends.

The cover protecting layer 500 that exposes the external connection pads PAD1 and PAD2 may be formed on the semiconductor substrate 110. The cover protecting layer 500 may cover the plurality of redistribution layers RD and the at least one stress balance pattern SB.

As shown in FIG. 7, and with reference to FIG. 12, the cover insulating layer 270 may include a plurality of first recesses RS1 and a plurality of second recesses RS2, a plurality of connection vias ICV may each fill a separate first recess RS1 of the plurality of first recesses RS1, and a plurality of stress balance patterns may each be on the cover insulating layer 270 and fill a separate second recess RS2 of the plurality of second recesses RS2.

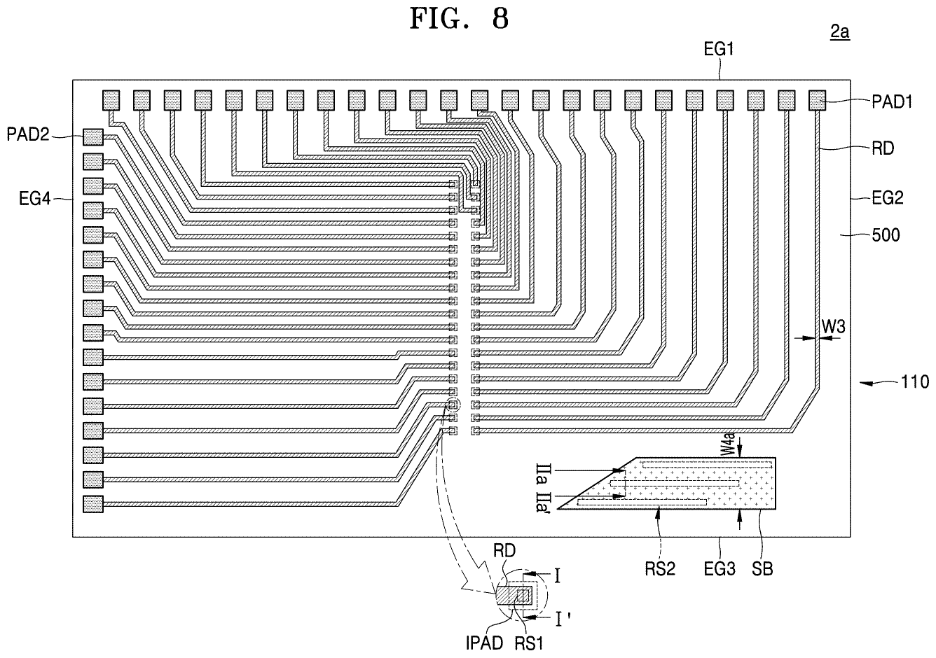

FIG. 8 is a plan view showing a semiconductor chip 2a according to some example embodiments of the inventive concepts.

Referring to FIG. 8, the semiconductor chip 2a includes the semiconductor substrate 110 and the plurality of redistribution layers RD disposed on the semiconductor substrate 110.

The semiconductor chip 2a may further include the at least one stress balance pattern SB unlike the semiconductor chip 1a shown in FIG. 2.

The at least one second recess RS2 may be disposed in a part of the semiconductor substrate 110 on which the redistribution layer RD is not disposed.

The first recess RS1 may extend from an upper surface to a lower surface to penetrate the cover insulating layer 270 (FIG. 12), and the at least one second recess RS2 may extend from the upper surface of the cover insulating layer 270 to the inside but may not extend to the lower surface. An extension length of the first recess RS1 may have a value greater than that of an extension length of the second recess RS2. For example, a depth of the first recess RS1 from an upper surface of the cover insulating layer 270 may have a value greater than that of a depth of the second recess RS2.

The at least one stress balance pattern SB filling the at least one second recess RS2 and spaced apart from (e.g., isolated from direct contact with) the plurality of redistribution layers RD may be disposed on the semiconductor substrate 110.

In some example embodiments, a width W4a of the stress balance pattern SB may have a value greater than that of the width W3 of the redistribution layer RD.

The cover protecting layer 500 that exposes the external connection pads PAD1 and PAD2 may be formed on the semiconductor substrate 110. The cover protecting layer 500 may cover the plurality of redistribution layers RD and the at least one stress balance pattern SB.

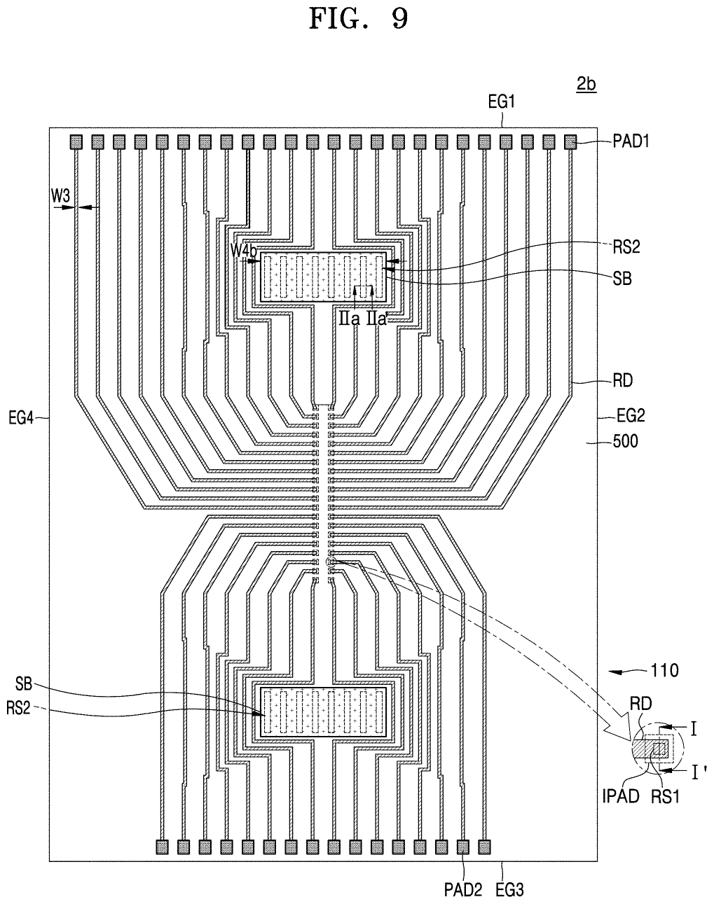

FIG. 9 is a plan view showing a semiconductor chip 2b according to some example embodiments of the inventive concepts.

Referring to FIG. 9, the semiconductor chip 2b includes the semiconductor substrate 110 and the plurality of redistribution layers RD disposed on the semiconductor substrate 110.

The semiconductor chip 2b may further include the at least one stress balance pattern SB unlike the semiconductor chip 1b shown in FIG. 3.

The at least one second recess RS2 may be disposed in a part of the semiconductor substrate 110 on which the redistribution layer RD is not disposed.

The first recess RS1 may extend from an upper surface to a lower surface to penetrate the cover insulating layer 270 (FIG. 12), and the at least one second recess RS2 may extend from the upper surface of the cover insulating layer 270 to the inside but may not extend to the lower surface. An extension length of the first recess RS1 may have a value greater than that of an extension length of the second recess RS2. For example, a depth of the first recess RS1 from an upper surface of the cover insulating layer 270 may have a value greater than that of a depth of the second recess RS2.

The at least one stress balance pattern SB filling the at least one second recess RS2 and spaced apart from (e.g., isolated from direct contact with) the plurality of redistribution layers RD may be disposed on the semiconductor substrate 110.

In some example embodiments, a width W4b of the stress balance pattern SB may have a value greater than that of the width W3 of the redistribution layer RD. The width W4b of the stress balance pattern SB may mean a width in a direction perpendicular to a direction in which the second recess RS2 extends or a width in a direction perpendicular to a direction in which the redistribution layer RD adjacent to the stress balance pattern SB extends.

The cover protecting layer 500 that exposes the external connection pads PAD1 and PAD2 may be formed on the semiconductor substrate 110. The cover protecting layer 500 may cover the plurality of redistribution layers RD and the at least one stress balance pattern SB.

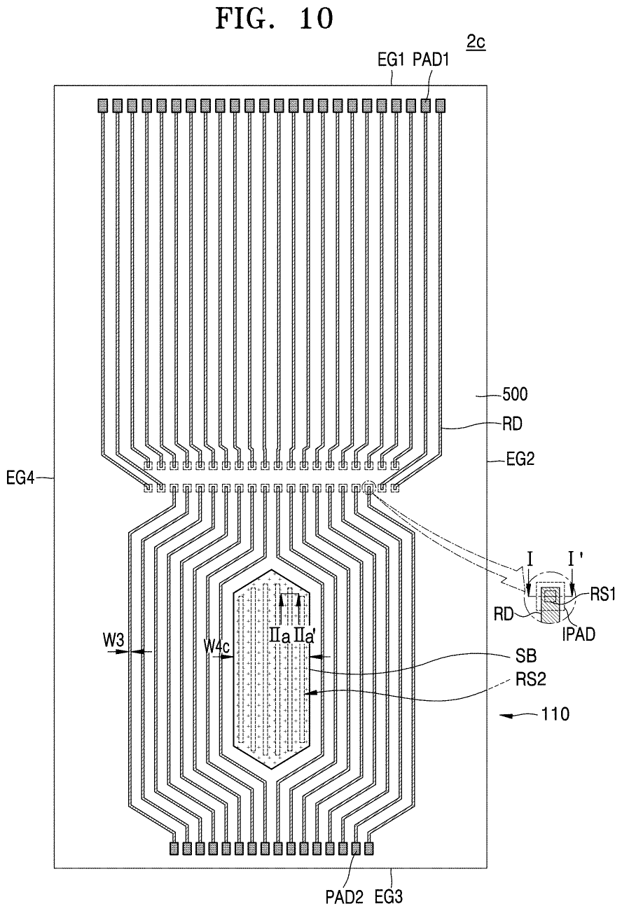

FIG. 10 is a plan view showing a semiconductor chip 2c according to some example embodiments of the inventive concepts.

Referring to FIG. 10, the semiconductor chip 2c includes the semiconductor substrate 110 and the plurality of redistribution layers RD disposed on the semiconductor substrate 110.

The semiconductor chip 2c may further include the at least one stress balance pattern SB unlike the semiconductor chip 1c shown in FIG. 4.

The at least one second recess RS2 may be disposed in a part of the semiconductor substrate 110 on which the redistribution layer RD is not disposed. For example, some of the plurality of redistribution layers RD may extend with a shape that bypasses the at least one second recess RS2.

The first recess RS1 may extend from an upper surface to a lower surface to penetrate the cover insulating layer 270 (FIG. 12), and the at least one second recess RS2 may extend from the upper surface of the cover insulating layer 270 to the inside but may not extend to the lower surface. An extension length of the first recess RS1 may have a value greater than that of an extension length of the second recess RS2. For example, a depth of the first recess RS1 from an upper surface of the cover insulating layer 270 may have a value greater than that of a depth of the second recess RS2.

The at least one stress balance pattern SB filling the at least one second recess RS2 and spaced apart from (e.g., isolated from direct contact with) the plurality of redistribution layers RD may be disposed on the semiconductor substrate 110.

In some example embodiments, a width W4c of the stress balance pattern SB may have a value greater than that of the width W3 of the redistribution layer RD. The width W4c of the stress balance pattern SB may mean a width in a direction perpendicular to a direction in which the second recess RS2 extends or a width in a direction perpendicular to a direction in which the redistribution layer RD adjacent to the stress balance pattern SB extends.

The cover protecting layer 500 that exposes the external connection pads PAD1 and PAD2 may be formed on the semiconductor substrate 110. The cover protecting layer 500 may cover the plurality of redistribution layers RD and the at least one stress balance pattern SB.

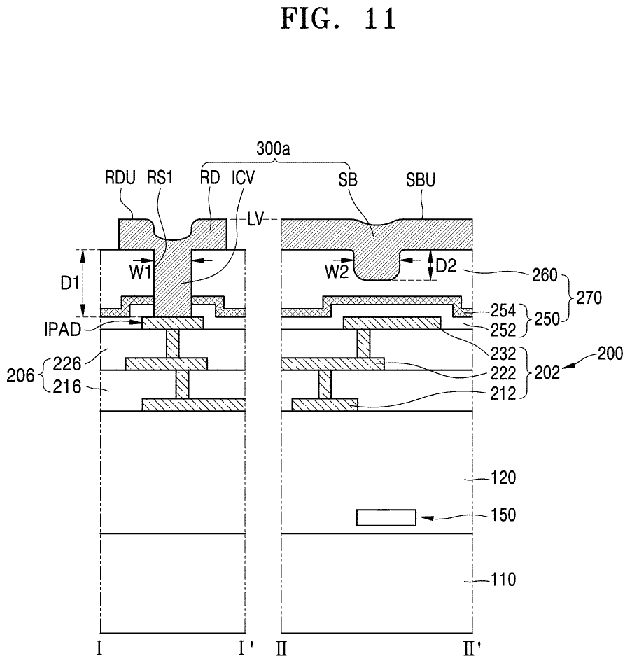

FIG. 11 is a cross-sectional view illustrating a method of manufacturing a semiconductor chip, according to some example embodiments of the inventive concepts. Specifically, FIG. 11 is the cross-sectional view showing the method of manufacturing any one of the semiconductor chips 2, 2a, 2b and 2c shown in FIGS. 7 to 10, and illustrates a cross-section corresponding to lines I-I′ and IIa-IIa′ of FIGS. 7 to 10, respectively.

Referring to FIG. 11, after operations similar to those described in FIGS. 5A to 5D are performed, a conductive material layer 300a filling the first recess RS1 and the second recess RS2 and disposed on a part of an upper surface of the cover insulating layer 270, that is, a part of an upper surface of the upper insulating layer 260 is formed. The conductive material layer 300a may include the connection via ICV filling the first recess RS1, the redistribution layer RD electrically connected to the connection via ICV and extending along the upper surface of the upper insulating layer 260, i.e., the upper surface of the cover insulating layer 270, and the stress balance pattern SB filling the second recess RS2, disposed on the upper surface of the upper insulating layer 260, and spaced apart from (e.g., isolated from direct contact with) the connection via ICV and the redistribution layer RD.

In some example embodiments, the connection via ICV, the redistribution layer RD, and the stress balance pattern SB may be formed together to include the same material. In some example embodiments, the uppermost end RDU (e.g., uppermost surface) of the redistribution layer RD and the uppermost end SBU (e.g., uppermost surface) of the stress balance pattern SB may be located at the same level LV, e.g., at a same distance from an upper surface 110a of the semiconductor substrate 110, and thus may be coplanar with each other. It will be understood that elements (e.g., surfaces) that are coplanar with each other may be substantially coplanar with each other (e.g., coplanar within manufacturing tolerances and/or material tolerances).

The conductive material layer 300a may configure at least some of the plurality of external connection pads PAD1 and PAD2 shown in FIGS. 7 to 10. For example, the plurality of external connection pads PAD1 and PAD2 may be a part of the conductive material layer 300a, or may include the part of the conductive material layer 300a and a metal layer covering an upper surface thereof.

FIG. 12 is a cross-sectional view showing the semiconductor chips 2, 2a, 2b, and 2c according to embodiments of the inventive concepts.

Referring to FIG. 12, the semiconductor chips 2, 2a, 2b, and 2c may include a device layer 120 on a semiconductor substrate 110. The device layer 120 may include a semiconductor device 150. Referring to FIG. 12, the semiconductor chips 2, 2a, 2b, and 2c may include a wiring structure 200 on the device layer 120. As shown in FIG. 12, the wiring structure 200 may include an internal connection pad IPAD that may be electrically connected to the semiconductor device 150. As shown in FIG. 12, the wiring structure 200 may include a plurality of wiring layers 202, a plurality of wiring vias 204 connected to the plurality of wiring layers 202, and at least one wiring insulating layer 206 filling between the plurality of wiring layers 202 and the plurality of wiring vias 204. As shown in FIG. 12, for example, the semiconductor chips 2, 2a, 2b, and 2c may include a first wiring layer 212 on the device layer 120, a first wiring via 214 on the device layer 120 and connected to the first wiring layer 212, and a first wiring insulating layer 216 at least partially between the first wiring layer 212 and the wiring via. Still referring to FIG. 12, the wiring layer 202 may include an internal connection pad IPAD. Still referring to FIG. 12, the semiconductor chips 2, 2a, 2b, and 2c may include a cover insulating layer 270. As shown in FIG. 12, the cover insulating layer 270 may include an upper surface 270U and a lower surface 270L. As shown, the cover insulating layer 270 may include a first recess RS1 that extends entirely through an interior of the cover insulating layer 270, from the upper surface 270U to the lower surface 270L, to expose the internal connection pad IPAD of the wiring layer 202. As further shown, the cover insulating layer 270 may include a second recess RS2 that extends into the interior of the cover insulating layer 270 from the upper surface 270U towards the lower surface 270L. For example, the second recess RS2 may extend from the upper surface 270U and through a limited portion of the interior of the cover insulating layer 270 such that the bottom surface RS2L is isolated from direct contact with the lower surface 270L. Still referring to FIG. 12, the semiconductor chips 2, 2a, 2b, and 2c may include a connection via ICV. As shown, the connection via ICV may fill (e.g., entirely fill) the first recess RS1. As shown, the connection via ICV may be connected to the internal connection pad IPAD. Still referring to FIG. 12, the semiconductor chips 2, 2a, 2b, and 2c may include a redistribution layer RD that is connected to the connection via ICV. The redistribution layer RD may extend along the upper surface 270U of the cover insulating layer 270. Still referring to FIG. 12, the semiconductor chips 2, 2a, 2b, and 2c may include a stress balance pattern SB on the cover insulating layer 270, where the stress balance pattern fills (e.g., entirely fills) the second recess RS2 and the stress balance pattern SB is isolated from direct contact with the redistribution layer RD.

Referring to FIG. 12, the semiconductor chips 2, 2a, 2b, and 2c may be formed by forming the redistribution layer RD, the stress balance pattern SB, and the cover protecting layer 500 covering the cover insulating layer 270. The cover protecting layer 500 may expose the plurality of external connection pads PAD1 and PAD2 shown in FIGS. 7 to 10 without covering them.

A depth of the first recess RS1 in which the connection via ICV is filled, that is, the first depth D1 from an upper surface 270U of the cover insulating layer 270 to an upper surface IPADU of the internal connection pad IPAD, may have a value (e.g., magnitude) greater than that (e.g., magnitude) of a depth of the second recess RS2 in which a part of the stress balance pattern SB is filled, that is, the second depth D2 from the upper surface 270U of the cover insulating layer 270 to the lowermost portion SBL of the stress balance pattern SB at the lower surface RS2L of the second recess RS2.

As shown in FIG. 12, and with reference to at least FIG. 7, the stress balance pattern SB may be on the cover insulating layer 270. The stress balance pattern SB may be isolated from direct contact with the redistribution layer RD. For example, stress balance pattern SB may be isolated from direct contact with the redistribution layer RD by at least the cover protecting layer 500. As shown in FIG. 12, the stress balance pattern SB may fill (e.g., entirely fill) the second recess RS2. Therefore, the stress balance pattern SB may be in contact with the lower surface of the second recess RS2. The lowermost end (e.g., lower surface SBL) of the stress balance pattern SB may be located at a level lower than (e.g., proximate to an upper surface 110a of the semiconductor substrate 110 in relation to) the uppermost end of the first recess RS1 (e.g., RS_U) and higher than (e.g., distal from the semiconductor substrate 110 in relation to) the lowermost end (e.g., RS_L). Where the semiconductor chips 2, 2a, 2b, and 2c include multiple first recesses RS1, the lowermost end (e.g. lower surface SBL) of the stress balance pattern SB may be located at a level lower than (e.g., proximate to an upper surface 110a of the semiconductor substrate 110 in relation to) the uppermost end of each of the first recesses RS1 (e.g., RS_U) and higher than (e.g., distal from the semiconductor substrate 110 in relation to) the lowermost end (e.g.,. RS1_L) of each of the first recesses RS1. In some example embodiments of the cover insulating layer 270, the lowermost end (e.g., lowermost surface SBL) of the stress balance pattern SB that is in contact (e.g., direct contact) with the lower surface of the second recess RS2 may be in contact (e.g., direct contact) with a portion of the upper insulating layer 260, but example embodiments are not limited thereto. For example, the lowermost end of the stress balance pattern SB in contact with the lower surface of the second recess RS2 may be in contact with a portion of the second passivation layer 254 or a portion of the first passivation layer 252.

Referring to FIGS. 7 to 12, in the semiconductor chips 2, 2a, 2b and 2c according to the inventive concepts, the second recess RS2 and the stress balance pattern SB filling the second recess RS2 and covering a part of an upper surface of the cover insulating layer 270 may be arranged in a part where stress caused by a difference in the thermal expansion coefficient of materials constituting the semiconductor chips 2, 2a, 2b and 2c may be concentrated, and thus the difference in the thermal expansion coefficient of materials constituting the semiconductor chips 2, 2a, 2b and 2c may be reduced, and a stress concentration may be released, which may prevent a warpage from occurring in the semiconductor chips 2, 2a, 2b and 2c.

As shown in FIGS. 7, 8, and 10, when there is the difference in the thermal expansion coefficient due to the plurality of redistribution layers RD that are non-uniformly arranged on the semiconductor chips 2, 2a, and 2c, the second recess RS2 and the stress balance pattern SB filling the second recess RS2 may be disposed in a part where the plurality of redistribution layers RD are not disposed, and thus the difference in the thermal expansion coefficient may be reduced, which may release the stress concentration that may occur in the semiconductor chips 2, 2a, and 2c.

In some example embodiments, as shown in FIG. 9, when there is the difference in the thermal expansion coefficient due to the inside of the semiconductor chip 2b, for example, the device layer 120, the plurality of wiring layers 202, and the plurality of wiring vias 204, the second recess RS2 and the stress balance pattern SB filling the second recess RS2 may be disposed in a corresponding part, and the plurality of redistribution layers RD may be bypassed to be spaced apart from (e.g., isolated from direct contact with) the second recess RS2 and the stress balance pattern SB, and thus the difference in the thermal expansion coefficient may be reduced, which may release the stress concentration that may occur in the semiconductor chip 2b.

In some example embodiments, at least a part of an arrangement of the second recess RS and the stress balance pattern SB may be applied together as shown in FIGS. 7 to 10 by comprehensively analyzing the difference in the thermal expansion coefficient that may occur in the semiconductor chips 2, 2a, 2b and 2c.

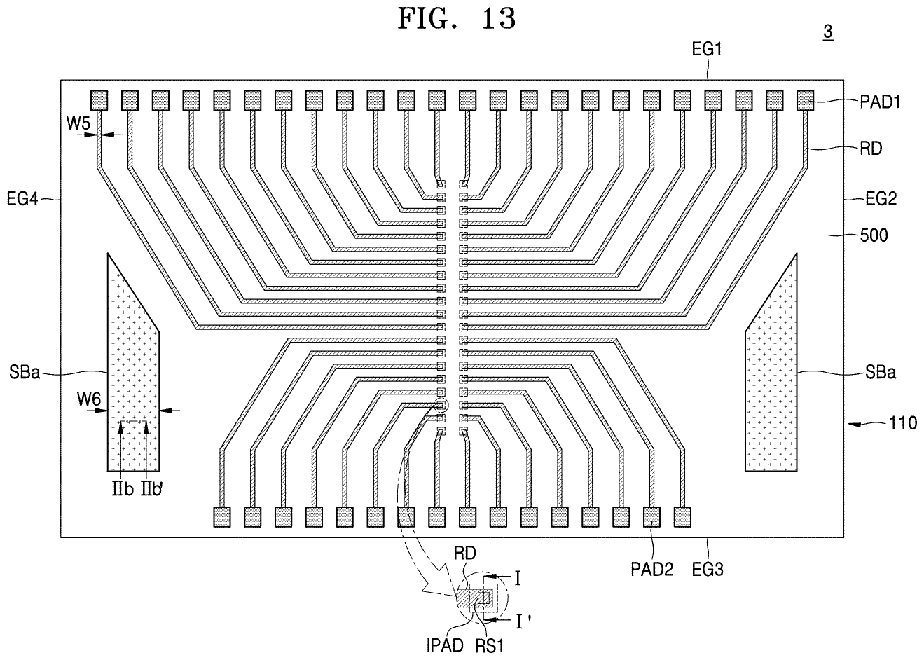

FIG. 13 is a plan view showing a semiconductor chip 3 according to some example embodiments of the inventive concepts.

Referring to FIG. 13, the semiconductor chip 3 includes the semiconductor substrate 110 and the plurality of redistribution layers RD disposed on the semiconductor substrate 110. The semiconductor chip 3 may not include the second recess RS2 unlike the semiconductor chip 2 shown in FIG. 7. Therefore, a configuration of the semiconductor chip 3 corresponding to the first recess RS1 of the semiconductor chip 2 shown in FIG. 7 may be called a recess RS.

The at least one stress balance pattern SB spaced apart from (e.g., isolated from direct contact with) the plurality of redistribution layers RD may be disposed on the semiconductor substrate 110. The at least one stress balance pattern SB may include the same material as the plurality of redistribution layers RD. In some example embodiments, the total material composition of the plurality of distribution layers RD may be the same as the total material composition of the at least one stress balance pattern SB.

In some example embodiments, a width W6 of the stress balance pattern SB may have a value greater than that of a width W5 of the redistribution layer RD. The width W6 of the stress balance pattern SB may mean a width in a minor axis direction of the stress balance pattern SB.

The cover protecting layer 500 that exposes the external connection pads PAD1 and PAD2 may be formed on the semiconductor substrate 110. The cover protecting layer 500 may cover the redistribution layer RD and the stress balance pattern SB.

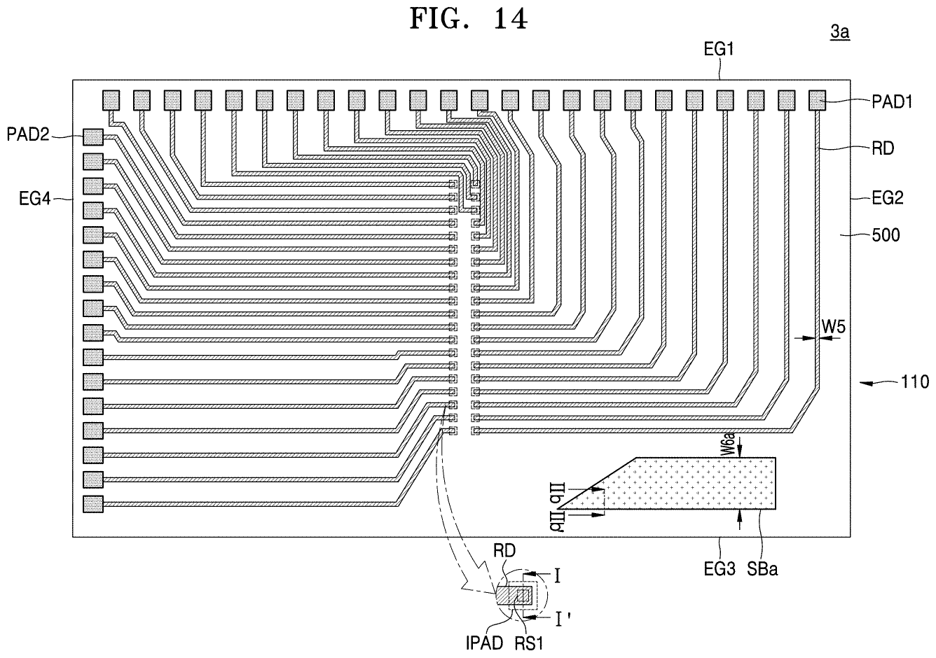

FIG. 14 is a plan view showing a semiconductor chip 3a according to some example embodiments of the inventive concepts.

Referring to FIG. 14, the semiconductor chip 3a includes the semiconductor substrate 110 and the plurality of redistribution layers RD disposed on the semiconductor substrate 110.

Unlike the semiconductor chip 2a shown in FIG. 8, the semiconductor chip 3a may not include the second recess RS2. Therefore, a configuration of the semiconductor chip 3a corresponding to the first recess RS1 of the semiconductor chip 2a shown in FIG. 8 may be called the recess RS.

The at least one stress balance pattern SB spaced apart from (e.g., isolated from direct contact with) the plurality of redistribution layers RD may be disposed on the semiconductor substrate 110.

In some example embodiments, a width W6a of the stress balance pattern SB may have a value greater than that of the width W5 of the redistribution layer RD. The width W6a of the stress balance pattern SB may mean a width in a minor axis direction of the stress balance pattern SB.

The cover protecting layer 500 that exposes the external connection pads PAD1 and PAD2 may be formed on the semiconductor substrate 110. The cover protecting layer 500 may cover the redistribution layer RD and the stress balance pattern SB.

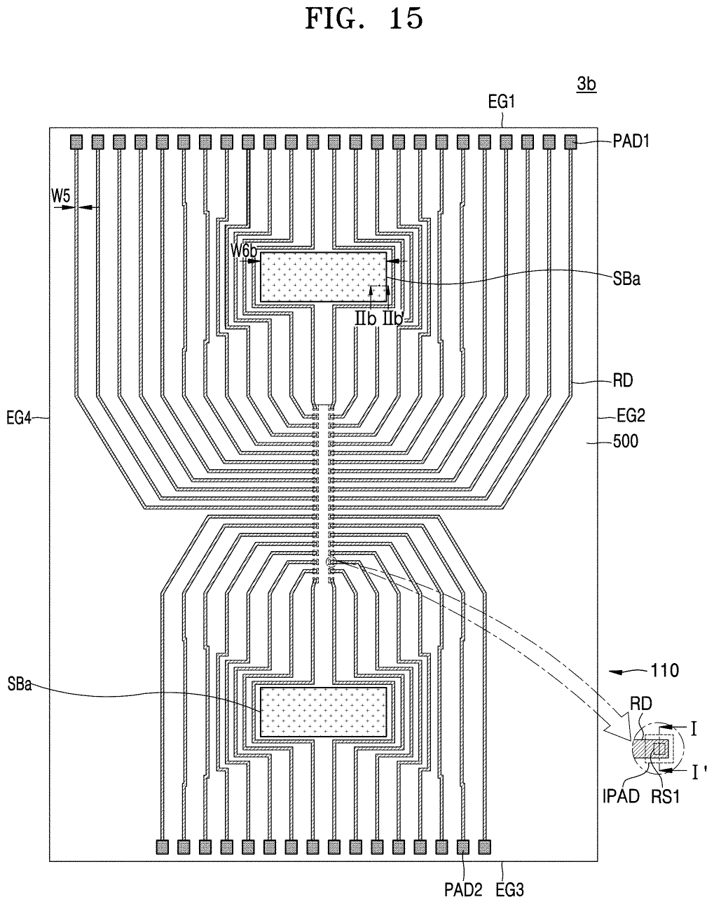

FIG. 15 is a plan view showing a semiconductor chip 3b according to some example embodiments of the inventive concepts.

Referring to FIG. 15, the semiconductor chip 3b includes the semiconductor substrate 110 and the plurality of redistribution layers RD disposed on the semiconductor substrate 110. The semiconductor chip 3b may not include the second recess RS2 unlike the semiconductor chip 1b shown in FIG. 9. Therefore, a configuration of the semiconductor chip 3b corresponding to the first recess RS1 of the semiconductor chip 2b shown in FIG. 9 may be called the recess RS.

The at least one stress balance pattern SB spaced apart from (e.g., isolated from direct contact with) the plurality of redistribution layers RD may be disposed on the semiconductor substrate 110.

In some example embodiments, a width W6b of the stress balance pattern SB may have a value greater than that of the width W5 of the redistribution layer RD. The width W6b of the stress balance pattern SB may mean a width in a direction perpendicular to a direction in which the redistribution layer RD adjacent to the stress balance pattern SB extends.

The cover protecting layer 500 that exposes the external connection pads PAD1 and PAD2 may be formed on the semiconductor substrate 110. The cover protecting layer 500 may cover the plurality of redistribution layers RD and the at least one stress balance pattern SB.

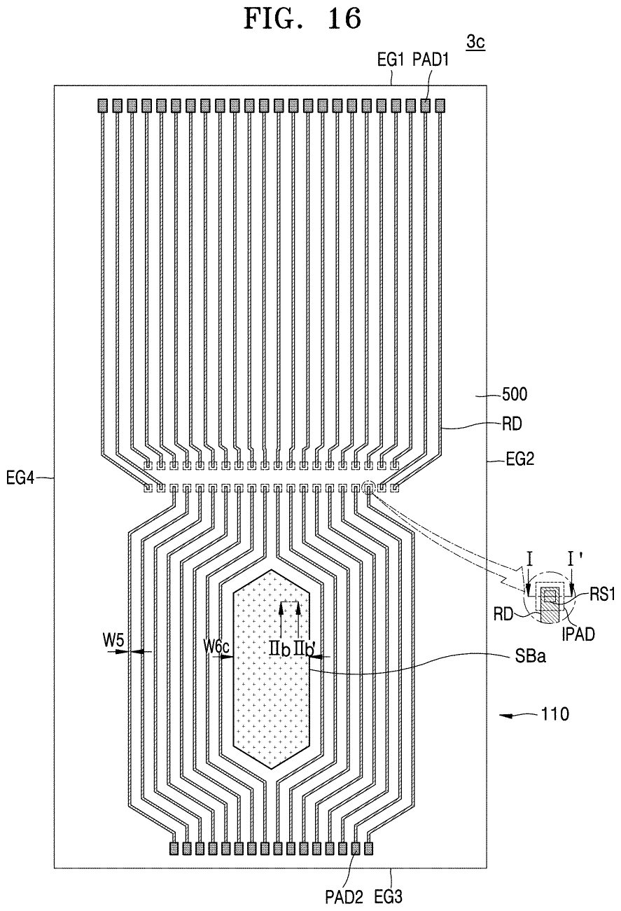

FIG. 16 is a plan view showing a semiconductor chip 3c according to some example embodiments of the inventive concepts.

Referring to FIG. 16, the semiconductor chip 3c includes the semiconductor substrate 110 and the plurality of redistribution layers RD disposed on the semiconductor substrate 110. The semiconductor chip 3c may not include the second recess RS2 unlike the semiconductor chip 2c shown in FIG. 10. Therefore, a configuration of the semiconductor chip 3c corresponding to the first recess RS1 of the semiconductor chip 2c shown in FIG. 10 may be called the recess RS.

The at least one stress balance pattern SB spaced apart from (e.g., isolated from direct contact with) the plurality of redistribution layers RD may be disposed on the semiconductor substrate 110.

In some example embodiments, a width W6c of the stress balance pattern SB may have a value greater than that of the width W5 of the redistribution layer RD. The width W6c of the stress balance pattern SB may mean a width in a direction perpendicular to a direction in which the redistribution layer RD adjacent to the stress balance pattern SB extends.

The cover protecting layer 500 that exposes the external connection pads PAD1 and PAD2 may be formed on the semiconductor substrate 110. The cover protecting layer 500 may cover the plurality of redistribution layers RD and the at least one stress balance pattern SB.

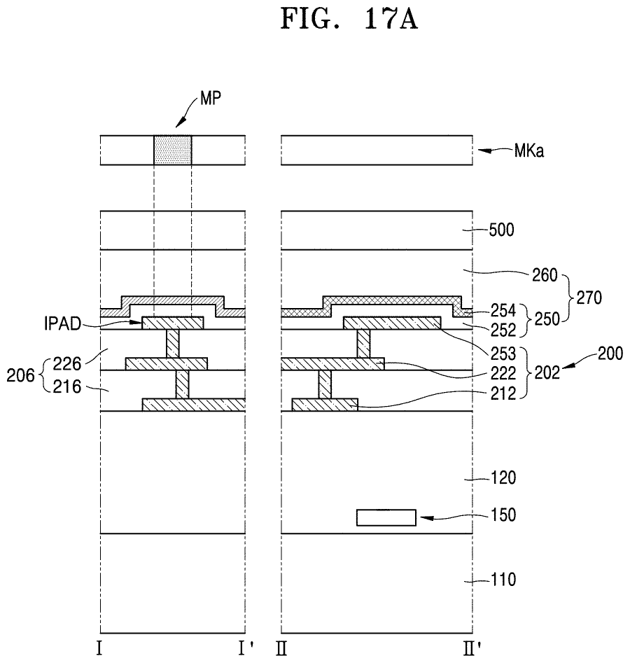

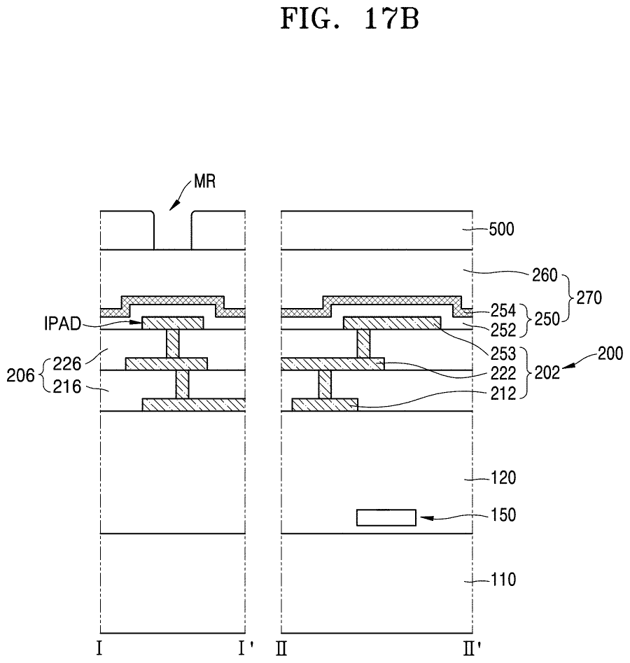

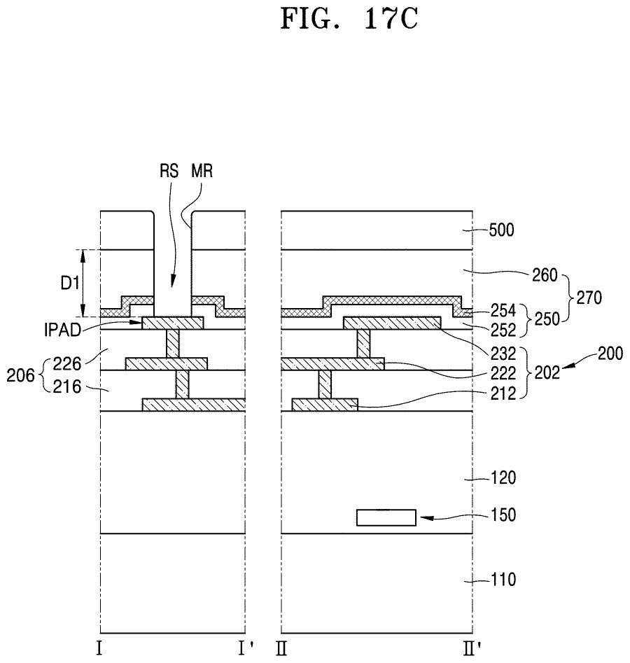

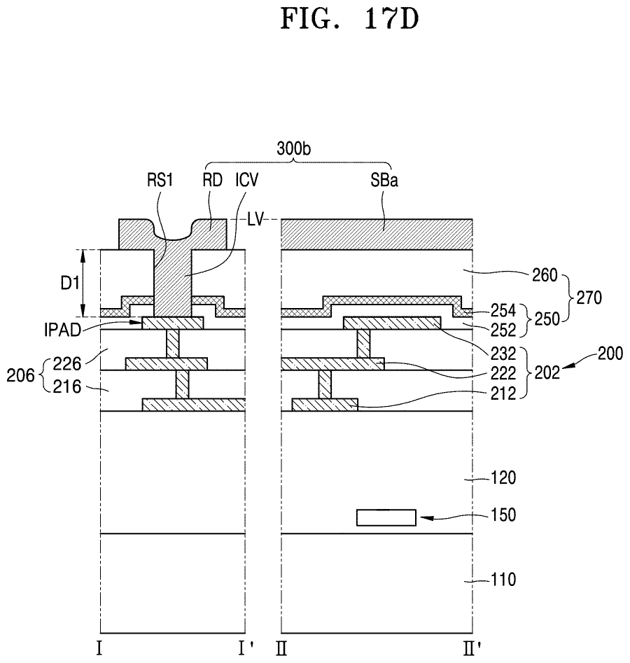

FIGS. 17A, 17B, 17C, and 17D are cross-sectional views sequentially illustrating a method of manufacturing a semiconductor chip, according to some example embodiments of the inventive concepts. Specifically, FIGS. 17A, 17B, 17C, and 17D are the cross-sectional views showing the method of manufacturing any one of the semiconductor chips 3, 3a, 3b and 3c shown in FIGS. 13 to 16, and illustrates a cross-section corresponding to lines I-I′ and IIb-IIb′ of FIGS. 13 to 16, respectively.

Referring to FIG. 17A, after an operation similar to that described in FIG. 5A is performed, the mask layer 400 covering the cover insulating layer 270 may be formed and then, a photomask MKa may be used to perform an exposure process on the mask layer 400. The photomask MKa may include the mask pattern MP corresponding to the first mask pattern MP1 of the photomask MK shown in FIG. 5B but may not have a configuration corresponding to the second mask pattern MP2 of the photomask MK shown in FIG. 5B.

The photomask MKa may be a negative mask, but is not limited thereto, and may be a positive mask. When the photomask MK is the negative mask, the mask pattern MP may block most of light irradiated from an exposure apparatus at a position corresponding to the internal connection pad IPAD.

Referring to FIGS. 17A and 17B, the exposure process using the photomask MKa is performed to form a mask recess MR corresponding to the mask pattern MP in the mask layer 400. The mask recess MR may penetrate the mask layer 400 from an upper surface to a lower surface and expose the cover insulating layer 270, that is, the upper insulating layer 260, on the lower surface.

Referring to FIG. 17C, an etching process is performed by using the mask layer 400 as an etch mask to remove a part of the cover insulating layer 270. A part of the cover insulating layer 270 corresponding to the mask recess MR is wholly removed such that the recess RS exposing the internal connection pad IPAD which is a part of the third wiring layer 232 may be formed.

After forming the recess RS, the mask layer 400 may be removed.

Referring to FIG. 17D, a conductive material layer 300b filling the recess RS and disposed on a part of the upper surface of the cover insulating layer 270, that is, a part of the upper surface of the upper insulating layer 260, is formed. The conductive material layer 300b may include the connection via ICV filling the recess RS, the redistribution layer RD electrically connected to the connection via ICV and extending along the upper surface of the upper insulating layer 260, i.e., the upper surface of the cover insulating layer 270, and a stress balance pattern SBa disposed on the upper surface of the upper insulating layer 260 and spaced apart from (e.g., isolated from direct contact with) the ICV and the redistribution layer RD. In some example embodiments, the connection via (ICV), the redistribution layer RD, and the stress balance pattern SBa may be formed together to include the same material. The conductive material layer 300a may configure at least some of the plurality of external connection pads PAD1 and PAD2 shown in FIGS. 13 to 16. For example, the plurality of external connection pads PAD1 and PAD2 may be a part of the conductive material layer 300a, or may include the part of the conductive material layer 300a and a metal layer covering an upper surface thereof.

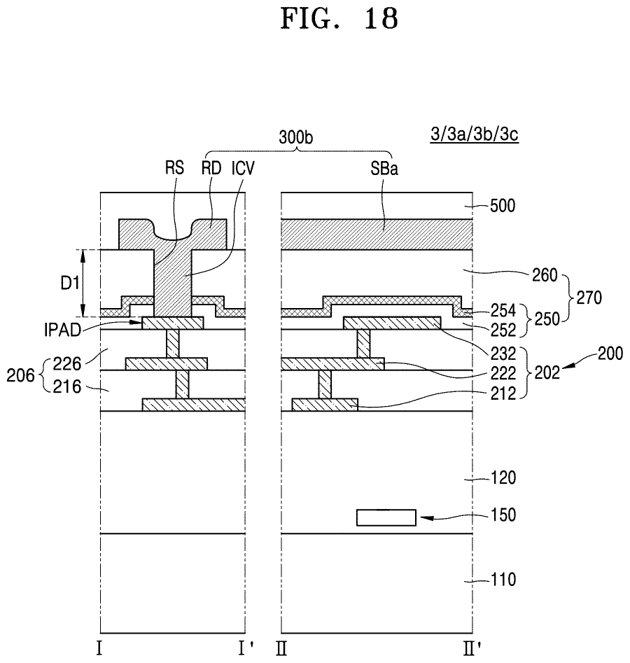

FIG. 18 is a cross-sectional view showing the semiconductor chips 3, 3a, 3b, and 3c according to embodiments of the inventive concepts.

Referring to FIG. 18, the semiconductor chips 3, 3a, 3b, and 3c may be formed by forming the redistribution layer RD, the stress balance pattern SBa, and the cover protecting layer 500 covering the cover insulating layer 270. The cover protecting layer 500 may expose the plurality of external connection pads PAD1 and PAD2 shown in FIGS. 13 to 16 without covering them.

Referring to FIGS. 13 to 18, in the semiconductor chips 3, 3a, 3b, and 3c according to the inventive concepts, the stress balance pattern SBa spaced apart from (e.g., isolated from direct contact with) the redistribution layer RD may be arranged in a part where stress caused by a difference in the thermal expansion coefficient of materials constituting the semiconductor chips 3, 3a, 3b, and 3c may be concentrated, and thus the difference in the thermal expansion coefficient of materials constituting the semiconductor chips 3, 3a, 3b, and 3c may be reduced, and a stress concentration may be released, which may prevent a warpage from occurring in the semiconductor chips 3, 3a, 3b, and 3c.

As shown in FIGS. 13, 14 and 16, when there is the difference in the thermal expansion coefficient due to the plurality of redistribution layers RD that are non-uniformly arranged on the semiconductor chips 3, 3a, and 3c, the stress balance pattern SBa may be disposed in a part where the plurality of redistribution layers RD are not disposed, and thus the difference in the thermal expansion coefficient may be reduced, which may release the stress concentration that may occur in the semiconductor chips 3, 3a, and 3c.

In some example embodiments, as shown in FIG. 15, when there is the difference in the thermal expansion coefficient due to the inside of the semiconductor chip 3b, for example, the device layer 120, the plurality of wiring layers 202, and the plurality of wiring vias 204, the stress balance pattern SBa may be disposed in a corresponding part, and the plurality of redistribution layers RD may be bypassed to be spaced apart from (e.g., isolated from direct contact with) the stress balance pattern SBa, and thus the difference in the thermal expansion coefficient may be reduced, which may release the stress concentration that may occur in the semiconductor chip 3b.

In some example embodiments, at least a part of the stress balance pattern SBa may be applied together as shown in FIGS. 13 to 16 by comprehensively analyzing the difference in the thermal expansion coefficient that may occur in the semiconductor chips 3, 3a, 3b and 3c.

Referring to FIGS. 1 to 18, although it is illustrated that the semiconductor chips 1, 1a, 1b, and 1c shown in FIGS. 1 to 6 include the second recess RS2 which is a stress release pattern in which the cover protecting layer 500 is filled, the semiconductor chips 2, 2a, 2b and 2c shown in FIGS. 7 to 12 include the second recess RS2 and the stress balance pattern SB filling the second recess RS2, and the semiconductor chips 3, 3a, 3b and 3c shown in FIGS. 13 to 18 include the stress balance pattern SBa disposed on the cover insulating layer 270, in consideration of a stress concentration that locally occurs in a semiconductor chip and intensity of concentrated stress, it is obvious to one of ordinary skill in the art to combine and apply these to the semiconductor chip.

For example, the semiconductor chip may include the second recess RS2 filled with the cover protecting layer 500 and the second recess RS2 filled with the stress balance pattern SB. In some example embodiments, the semiconductor chip may include a stress balance pattern SB that fills the second recess RS2 and a stress balance pattern SBa that is disposed on the cover insulating layer 270. In some example embodiments, for example, the semiconductor chip may include the second recess RS2 filled with the cover protecting layer 500 and the stress balance pattern SBa disposed on the cover insulating layer 270. In some example embodiments, for example, the semiconductor chip may include the second recess RS2 filled with the cover protecting layer 500, the second recess RS2 filled with the stress balance pattern SB, and the stress balance pattern SBa disposed on the cover insulating layer 270.

While the inventive concepts have been particularly shown and described with reference to example embodiments thereof, it will be understood that various changes in form and details may be made therein without departing from the spirit and scope of the following claims.

What is claimed is:

1. A semiconductor chip, comprising:
a device layer on a semiconductor substrate, the device layer including a semiconductor device;
a wiring structure on the device layer, the wiring structure including an internal connection pad electrically connected to the semiconductor device;
a cover insulating layer on the wiring structure, the cover insulating layer including
a first recess, the first recess filled with a connection via, the connection via connected to the internal connection pad, and
a second recess, a magnitude of a depth of the second recess being less than a magnitude of a depth of the first recess; and
a redistribution layer connected to the connection via and extending along an upper surface of the cover insulating layer.

2. The semiconductor chip of claim 1, wherein
a magnitude of a width of the second recess is greater than a magnitude of a width of the first recess.

3. The semiconductor chip of claim 1, further comprising:
a cover protecting layer filling the second recess and covering the redistribution layer and the cover insulating layer.

4. The semiconductor chip of claim 1, further comprising:
a stress balance pattern on the cover insulating layer, the stress balance pattern isolated from direct contact with the redistribution layer, the stress balance pattern filling the second recess.

5. The semiconductor chip of claim 4, wherein
the stress balance pattern includes a same material as the redistribution layer.

6. The semiconductor chip of claim 4, wherein
an uppermost surface of the redistribution layer is coplanar with an uppermost surface of the stress balance pattern.

7. The semiconductor chip of claim 4, wherein
a magnitude of a width of the stress balance pattern is greater than a magnitude of a width of the redistribution layer.

8. The semiconductor chip of claim 1, wherein
the cover insulating layer includes a plurality of first recesses, the plurality of first recesses including the first recess, and
the semiconductor chip includes a plurality of redistribution layers, the plurality of redistribution layers including the redistribution layer, the plurality of redistribution layers connected to separate, respective connection vias of a plurality of connection vias, the plurality of connection vias filling separate, respective first recesses of the plurality of first recesses.

9. The semiconductor chip of claim 8, further comprising:
a plurality of external connection pads,
wherein a first end of each redistribution layer of the plurality of redistribution layers is connected to a separate external connection pad of the plurality of external connection pads,
wherein an opposite, second end of each redistribution layer of the plurality of redistribution layers is connected to a separate connection via of the plurality of connection vias.

10. The semiconductor chip of claim 9, wherein,
the plurality of external connection pads includes a first set of external connection pads and a second set of external connection pads, the first set of external connection pads adjacent to a first edge of the semiconductor substrate, the second set of external connection pads adjacent to a second edge of the semiconductor substrate, the first and second edges being opposite edges of the semiconductor substrate, the first and second sets of external connection pads including different quantities of external connection pads, or
the plurality of external connection pads includes a first set of external connection pads and a second set of external connection pads, the first set of external connection pads adjacent to a first edge of the semiconductor substrate, the second set of external connection pads adjacent to a second edge of the semiconductor substrate, the first and second edges being connected to each other, the first and second sets of external connection pads including different quantities of external connection pads.

11. A semiconductor chip, comprising:
a device layer on a semiconductor substrate;
a wiring layer on the device layer, a wiring via on the device layer and connected to the wiring layer, and a wiring insulating layer at least partially between the wiring layer and the wiring via, the wiring layer including an internal connection pad;
a cover insulating layer including
a first recess extending through an interior of the cover insulating layer, from an upper surface of the cover insulating layer to a lower surface of the cover insulating layer, to expose the internal connection pad of the wiring layer, and
a second recess extending into the interior of the cover insulating layer from the upper surface of the cover insulating layer towards the lower surface of the cover insulating layer;
a connection via filling the first recess, the connection via connected to the internal connection pad;
a redistribution layer connected to the connection via, the redistribution layer extending along the upper surface of the cover insulating layer; and
a stress balance pattern on the cover insulating layer, the stress balance pattern filling the second recess, the stress balance pattern isolated from direct contact with the redistribution layer.

12. The semiconductor chip of claim 11, wherein
a magnitude of a depth from the upper surface of the cover insulating layer to the upper surface of the internal connection pad is greater than a magnitude of a depth from the upper surface of the cover insulating layer to a lower surface of the second recess.

13. The semiconductor chip of claim 11, wherein
a magnitude of a width of the stress balance pattern is greater than a magnitude of a width of the redistribution layer, and
an uppermost surface of the stress balance pattern is coplanar with an uppermost surface of the redistribution layer.

14. The semiconductor chip of claim 11, wherein
the cover insulating layer includes a plurality of first recesses, the plurality of first recesses including the first recess,
the cover insulating layer includes a plurality of second recesses, the plurality of second recesses including the second recess,
the semiconductor chip includes a plurality of connection vias, the plurality of connection vias including the connection via, each connection via of the plurality of connection vias filling a separate first recess of the plurality of first recesses,
the semiconductor chip includes a plurality of stress balance patterns, the plurality of stress balance patterns including the stress balance pattern, each stress balance pattern of the plurality of stress balance patterns on the cover insulating layer and filling a separate second recess of the plurality of second recesses.

15. The semiconductor chip of claim 11, wherein
the cover insulating layer includes
a passivation layer, and
an upper insulating layer on the passivation layer, and
a lowermost surface of the stress balance pattern is in direct contact with the upper insulating layer.

16. A semiconductor chip comprising:
a device layer on a semiconductor substrate;
a plurality of wiring layers on the device layer, a plurality of wiring vias connected to the plurality of wiring layers, and a wiring insulating layer filling between the plurality of wiring layers and the plurality of wiring vias, the plurality of wiring layers including a plurality of internal connection pads;
a cover insulating layer including a plurality of connection via holes extending through an interior of the cover insulating layer from an upper surface of the cover insulating layer to a lower surface of the cover insulating layer to expose the plurality of internal connection pads;
a plurality of connection vias filling separate, respective connection via holes of the plurality of connection via holes;
a plurality of redistribution layers connected to separate, respective connection vias of the plurality of connection vias, the plurality of redistribution layers extending along the upper surface of the cover insulating layer; and
a stress balance pattern on the cover insulating layer, the stress balance pattern isolated from direct contact with the plurality of redistribution layers.

17. The semiconductor chip of claim 16, wherein
the plurality of internal connection pads are center pads arranged along a center of the semiconductor substrate.

18. The semiconductor chip of claim 17, further comprising:
a plurality of external connection pads,
wherein a first end of each redistribution layer of the plurality of redistribution layers is connected to a separate external connection pad of the plurality of external connection pads,
wherein an opposite, second end of each redistribution layer of the plurality of redistribution layers is connected to a separate connection via of the plurality of connection vias,
wherein the plurality of external connection pads are edge pads arranged along at least one edge of the semiconductor substrate.

19. The semiconductor chip of claim 18, wherein,
the plurality of external connection pads includes a first set of external connection pads and a second set of external connection pads, the first set of external connection pads adjacent to a first edge of the semiconductor substrate, the second set of external connection pads adjacent to a second edge of the semiconductor substrate, the first and second edges being opposite edges of the semiconductor substrate, the first and second sets of external connection pads including different quantities of external connection pads.

20. The semiconductor chip of claim 16, wherein
a lowermost end of the stress balance pattern is
proximate to an upper surface of the semiconductor substrate in relation to an uppermost end of each of the plurality of connection via holes, and
distal to the upper surface of the semiconductor substrate in relation to a lowermost end of each of the plurality of connection via holes.
